(19) United States
(12) Patent Application Publication
(10) Pub. No.: US 2015/0200008 A1
(43) Pub. Date: Jul. 16, 2015

(54) SEMICONDUCTOR PACKAGE AND ELECTRONIC APPARATUS

(71) Applicant: Kabushiki Kaisha Toshiba, Minato-ku (JP)

(72) Inventors: Isao OZAWA, Chigasaki-shi (JP); Akira TANIMOTO, Yokohama-shi (JP); Eigo MATSUURA, Yamato-shi (JP); Katsuya MURAKAMI, Sumida-ku (JP); Yasuo KUDO, Higashiyamato-shi (JP); Koichi NAGAI, Ota-ku (JP)

(73) Assignee: Kabushiki Kaisha Toshiba, Minato-ku (JP)

(21) Appl. No.: 14/321,166

(22) Filed: Jul. 1, 2014

(30) Foreign Application Priority Data
Jan. 16, 2014 (JP) 2014-006242

(51) Int. Cl. G11C 14/00; H01L 25/16; H01L 25/065; H01L 23/31; H01L 23/00; G11C 5/02; H01L 23/34

(52) U.S. Cl. CPC G11C 14/0018; G11C 5/025; H01L 25/16; H01L 23/34; H01L 23/3142; H01L 24/17; H01L 25/0657; H01L 2225/06562; H01L 2225/06506; H01L 2924/14511; H01L 2224/17519; H01L 2224/17134; H01L 2924/1436; H01L 2924/1443; H01L 2224/49107; H01L 2224/4912; H01L 2224/48147; H01L 2224/48227; H01L 2224/17154

(57) ABSTRACT

According to one embodiment, a semiconductor package includes a package substrate, a controller chip, a semiconductor memory chip, a temperature sensor, a seal portion, and a plurality of solder balls. The controller chip and the semiconductor memory chip are provided on a first surface of the package substrate. The temperature sensor is provided at a position along an edge of the first surface, which is at a center portion separated away from corner portions. The plurality of solder balls is provided on a second surface that is at an opposite side of the first surface.

### CROSS-REFERENCE TO RELATED APPLICATIONS

This application is based upon and claims the benefit of priority from Japanese Patent Application No. 2014-006242, filed on Jan. 16, 2014; the entire contents of which are incorporated herein by reference.

### FIELD

Embodiments described herein relate generally to a semiconductor package and an electronic apparatus.

### BACKGROUND

A semiconductor package including semiconductor memory chips is provided. There are demands for an improved high speed operability of the semiconductor package. Embodiments disclosed herein aim to provide a semiconductor package and an electronic apparatus that can improve the high speed operability.

### BRIEF DESCRIPTION OF THE DRAWINGS

FIG. 1 is a perspective diagram illustrating an example of an electronic apparatus of a first embodiment;

FIG. 2 is a diagram illustrating an example of a configuration of a part of a circuit board illustrated in FIG. 1;

FIG. 3 is a diagram illustrating an example of a configuration of a semiconductor package illustrated in FIG. 1;

FIG. 4 is a cross sectional diagram illustrating an example of the semiconductor package illustrated in FIG. 1;

FIG. 5 is a cross sectional diagram illustrating an example of a first modification of the semiconductor package illustrated in FIG. 1;

FIG. 6 is a cross sectional diagram illustrating an example of a second modification of the semiconductor package illustrated in FIG. 1;

FIG. 7 is a bottom surface diagram illustrating an example of a bottom surface of the semiconductor package illustrated in FIG. 1;

FIG. 8 is a diagram illustrating an example of an assignment of solder balls illustrated in FIG. 7;

FIG. 9 is a diagram illustrating an example of contents of the assignment illustrated in FIG. 8;

FIG. 10 is a plan diagram illustrating an example of pads of a circuit board of the first embodiment;

FIG. 11 is a plan diagram illustrating a temperature distribution in the semiconductor package in a case of arranging the solder balls as illustrated in FIGS. 7 and 8;

FIG. 12 is a bottom diagram of the semiconductor package illustrating another example of solder ball arrangement as a comparative example;

FIG. 13 is a plan diagram illustrating a temperature distribution in the semiconductor package in a case of arranging the solder balls as illustrated in FIG. 12;

FIG. 14 is a bottom diagram of the semiconductor package illustrating another example of solder ball arrangement as another comparative example;

FIG. 15 is a plan diagram illustrating a temperature distribution in the semiconductor package in a case of arranging the solder balls as illustrated in FIG. 14;

FIG. 16 is a bottom diagram of the semiconductor package illustrating another example of solder ball arrangement as yet another comparative example;

FIG. 17 is a plan diagram illustrating a temperature distribution in the semiconductor package in a case of arranging the solder balls as illustrated in FIG. 16;

FIG. 18 is a plan diagram for explaining a positional relationship of electronic components arranged in the semiconductor package;

FIG. 19 is a diagram illustrating a temperature change in a case of operating semiconductor memory chips intermittently;

FIG. 20 is a diagram illustrating an example of an assignment of solder balls in a semiconductor package of a second embodiment;

FIG. 21 is a diagram illustrating a magnified example of a region surrounded by a line F12 in the semiconductor package illustrated in FIG. 20;

FIG. 22 is a plan diagram illustrating an example of pads of a circuit board of the second embodiment;

FIG. 23 is a diagram schematically illustrating an example of some of signal lines illustrated in FIG. 22;

FIG. 24 is a diagram schematically illustrating an example of a first modification of the signal lines illustrated in FIG. 22;

FIG. 25 is a diagram schematically illustrating an example of a second modification of the signal lines illustrated in FIG. 22;

FIG. 26 is a diagram illustrating an example of an assignment of solder balls in a semiconductor package of a third embodiment;

FIG. 27 is a diagram illustrating a magnified example of a region surrounded by a line F182 in the semiconductor package illustrated in FIG. 26;

FIG. 28 is a diagram schematically illustrating an example of some of signal lines of the third embodiment;

FIG. 29 is a diagram illustrating an example of an assignment of solder balls in a semiconductor package of a fourth embodiment;

FIG. 30 is a diagram illustrating a magnified example of a region surrounded by a line F21 in the semiconductor package illustrated in FIG. 29;

FIG. 31 is a diagram schematically illustrating an example of some of signal lines of the fourth embodiment;

FIG. 32 is a cross sectional diagram illustrating a semiconductor package of a fifth embodiment; and

FIG. 33 is a bottom diagram illustrating a semiconductor package of a sixth embodiment.

### DETAILED DESCRIPTION

In general, according to one embodiment, a semiconductor package includes a package substrate, a controller chip, a semiconductor memory chip, a temperature sensor, a seal portion, and a plurality of solder balls. The package substrate includes a first surface. The controller chip is provided on the first surface of the package substrate. The semiconductor memory chip is stacked on the controller chip. The temperature sensor is provided at a position along an edge of the first surface, which is at a center portion separated away from corner portions. The seal portion is provided on the first surface and is configured to cover the controller chip, the semiconductor memory chip, and the temperature sensor. The plurality of solder balls is provided on a second surface that is at an opposite side of the first surface.

Exemplary embodiments of a semiconductor package and an electronic apparatus will be explained below in detail with reference to the accompanying drawings. The present invention is not limited to the following embodiments.

### First Embodiment

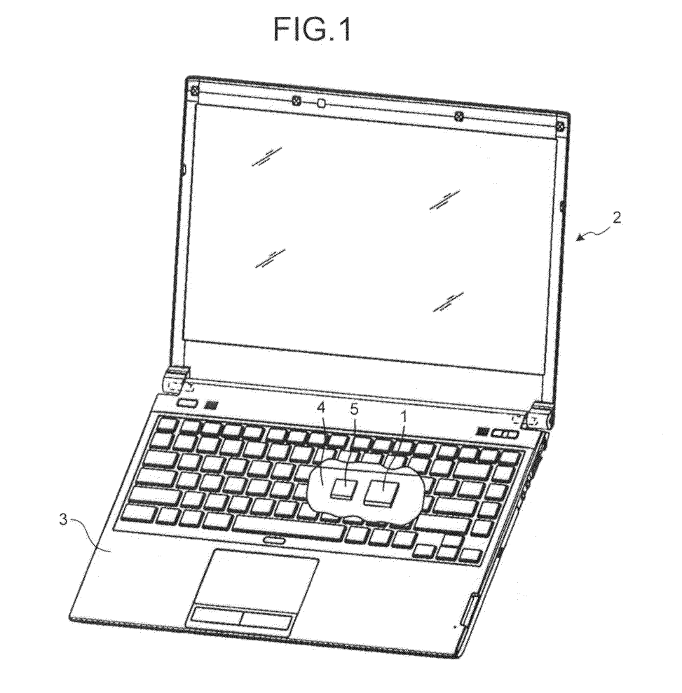

FIGS. 1 to 10 illustrate a semiconductor package 1 of a first embodiment. The semiconductor package 1 is an example of a “semiconductor device”, and a “semiconductor memory device”, respectively. The semiconductor package 1 of the embodiment is a so-called BGA-SSD (Ball Grid Array-Solid State Drive), and a plurality of semiconductor memory chips and a controller are integrally configured as one BGA type package.

FIG. 1 illustrates an example of an electronic apparatus 2 in which the semiconductor package 1 is mounted. The electronic apparatus 2 is an example of a “system”, a “device”, and a “unit”, respectively. The electronic apparatus 2 includes a housing 3, and a circuit board 4 (for example, a main board) housed in the housing 3. The semiconductor package 1 is attached to the circuit board 4, and functions as a storage device of the electronic apparatus 2. The circuit board 4 includes a host controller 5 (for example, a CPU). The host controller 5 includes a south bridge, for example, and controls operations of an entirety of the electronic apparatus 2 including the semiconductor package 1.

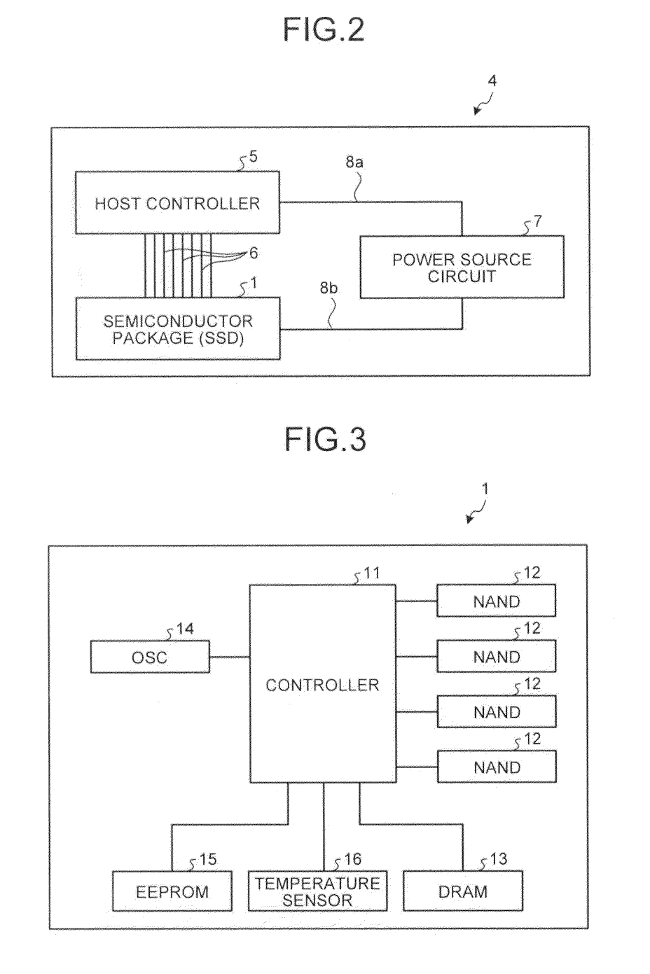

FIG. 2 schematically illustrates a part of the configuration of the circuit board 4. The host controller 5 and the semiconductor package 1 of the embodiment includes interfaces complying with the standard of PCI Express (hereinbelow PCIe). A plurality of signal lines 6 is provided between the host controller 5 and the semiconductor package 1. The semiconductor package 1 sends and receives high speed signals complying with the PCIe standard with the host controller 5 via the signal lines 6.

The circuit board 4 is provided with a power source circuit 7. The power source circuit 7 is connected to the host controller 5 and the semiconductor package 1 via power source lines 8a, 8b. The power source circuit 7 supplies various power sources to the host controller 5 and the semiconductor package 1 which are for the electronic apparatus 2 to operate.

Next, a configuration of the semiconductor package 1 will be described. FIG. 3 is a block diagram illustrating an example of the configuration of the semiconductor package 1. The semiconductor package 1 includes a controller chip 11, semiconductor memory chips 12, a DRAM chip 13, an oscillator (OSC) 14, an electrically erasable and programmable ROM (EEPROM) 15, and a temperature sensor 16.

The controller chip 11 (that is, a controller) is a semiconductor chip that controls operations of the semiconductor memory chips 12. The semiconductor memory chips 12 are for example NAND chips (NAND flash memories). The NAND chips are nonvolatile memories, and retain data even in a state where power supply is not performed. The DRAM chip 13 is used for storing management information of the semiconductor memory chips 12, and data cache.

The oscillator (OSC) 14 supplies operation signals of a predetermined frequency to the controller chip 11. The EEPROM 15 stores control program and the like as fixed information. The EEPROM 15 is an example of a nonvolatile memory. The temperature sensor 16 detects temperature in the semiconductor package 1, and notifies the same to the controller chip 11.

The controller chip 11 controls operations of respective sections of the semiconductor package 1 by using temperature information received from the temperature sensor 16. For example, in a case where the temperature detected by the temperature sensor 16 is at a predetermined value or higher, the controller chip 11 reduces an operation speed of the semiconductor package 1, or stops the operation of the semiconductor package 1 for a predetermined time or at a predetermined interval so as to suppress the temperature of the semiconductor package 1 at an allowable value or lower.

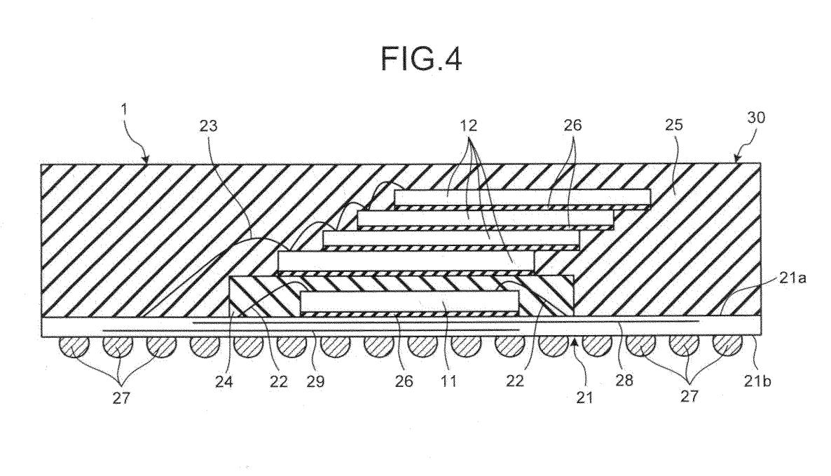

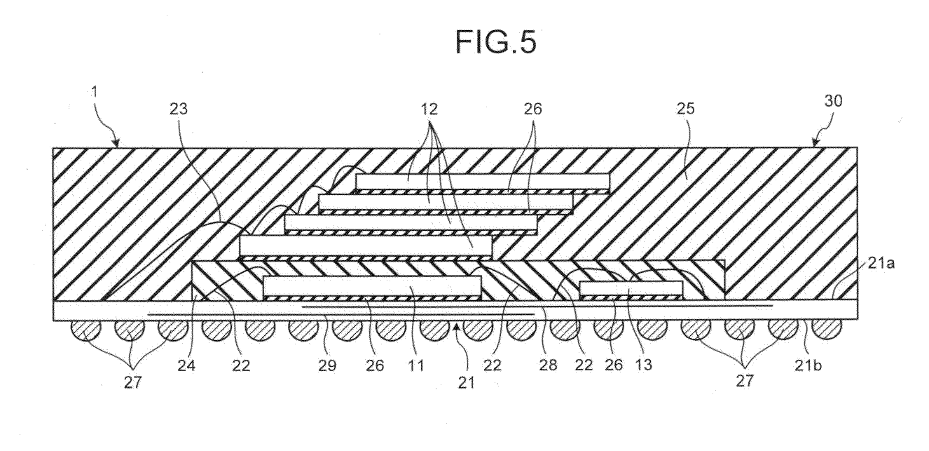

Next, the configuration of the semiconductor package 1 will be described. FIG. 4 is a cross sectional diagram of the semiconductor package 1. The semiconductor package 1 includes a substrate 21 (package substrate), the controller chip 11, the semiconductor memory chips 12, bonding wires 22, 23, molding portions 24, 25, mount films 26, and a plurality of solder balls 27.

The substrate 21 is a multilayer circuit board, and includes a power source layer 28 and a ground layer 29. The substrate 21 includes a first surface 21a, and a second surface 21b positioned on an opposite side of the first surface 21a. The controller chip 11 is mounted on the first surface 21a of the substrate 21. The controller chip 11 is for example fixed to the substrate 21 by a mount film 26. Further, the controller chip 11 is electrically connected to the substrate 21 by the bonding wires 22.

A first molding portion 24 for sealing the controller chip 11 and the bonding wires 22 is provided on the first surface 21a of the substrate 21. Notably, a thick mount film may be used instead of the first molding portion 24. According to the above, a mold type semiconductor package (first molded package) that seals the controller chip 11 is formed.

As illustrated in FIG. 4, the plurality of semiconductor memory chips 12 is stacked on the first molding portion 24. The plurality of semiconductor memory chips 12 is fixed on the first molding portion 24 by mount films 26. The plurality of semiconductor memory chips 12 is electrically connected to the substrate 21 via the bonding wires 23. The semiconductor memory chips 12 are electrically connected to the controller chip 11 via the substrate 21.

A second molding portion 25 for sealing the first molding portion 24, the plurality of semiconductor memory chips 12, and the bonding wires 23 is provided on the first surface 21a of the substrate 21. According to the above, in the embodiment, a seal portion 30 provided on the first surface 21a of the substrate 21 is formed by the first molding portion 24 and the second molding portion 25. The seal portion 30 integrally covers the controller chip 11, the plurality of semiconductor memory chips 12, the oscillator 14, the EEPROM 15, and the temperature sensor 16.

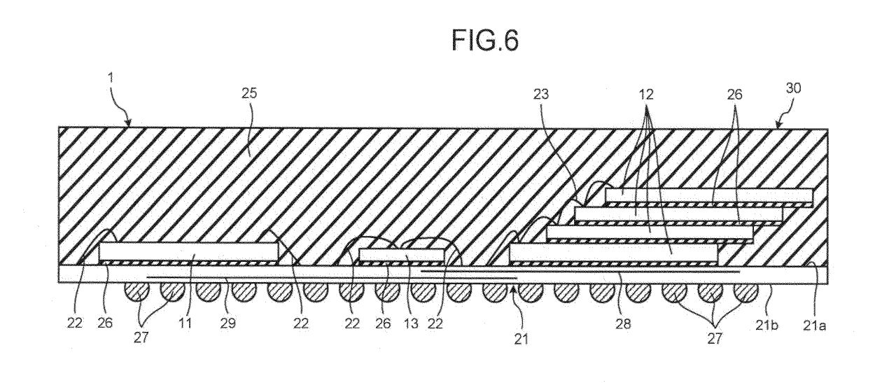

FIG. 5 illustrates a first modification of the semiconductor package 1 of the embodiment. In this first modification, a DRAM chip 13 is mounted on the first surface 21a of the substrate 21. The DRAM chip 13 is covered by the first molding portion 24. Notably, the DRAM chip 13 may be positioned outside of the first molding portion 24, and may be covered by the second molding portion 25.

FIG. 6 illustrates a second modification of the semiconductor package 1 of the embodiment. In this second modification, the plurality of semiconductor memory chips 12 is stacked on the first surface 21a of the substrate 21. That is, the plurality of semiconductor memory chips 12 is disposed on a lateral side of the controller chip 11 and the DRAM chip 13.

In the present modification, a single molding portion 25 integrally covers the controller chip 11, the DRAM chip 13, and the plurality of semiconductor memory chips 12. In this case, the seal portion 30 provided on the first surface 21a of the substrate 21 is formed by the single molding portion 25. Notably, the seal portion 30 of the semiconductor package 1 is not limited to those formed by molding portions, but may be formed of other materials such as a ceramic material.

Next, the plurality of solder balls 27 provided on the substrate 21 will be described. As illustrated in FIG. 4, the plurality of solder balls 27 for external connection is provided on the second surface 21b of the substrate 21. In the embodiment, the solder balls 27 are arranged for example at 0.5 mm pitch.

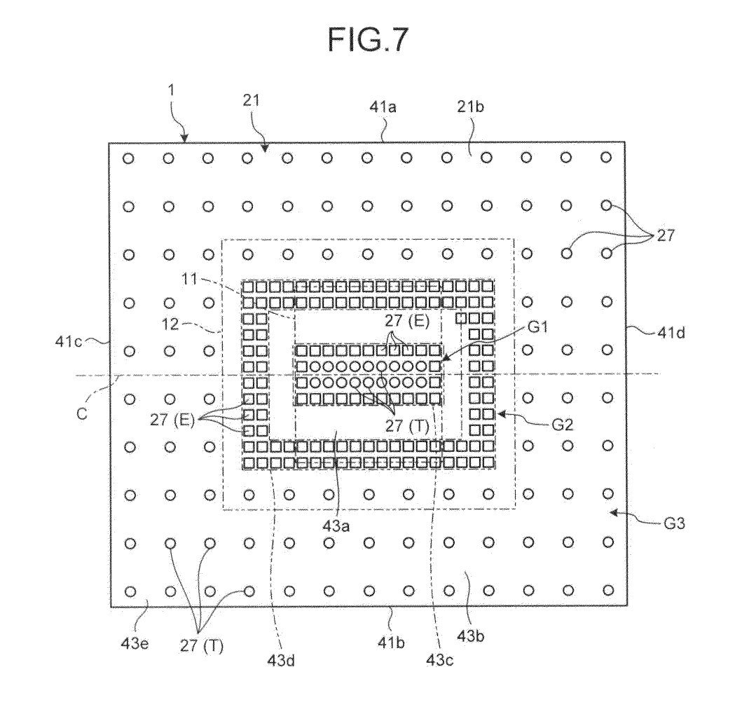

FIG. 7 illustrates an arrangement of the solder balls 27 on the second surface 21b of the substrate 21. As illustrated in FIG. 7, the plurality of solder balls 27 is not arranged fully on the entire second surface 21b of the substrate 21, but is arranged partially.

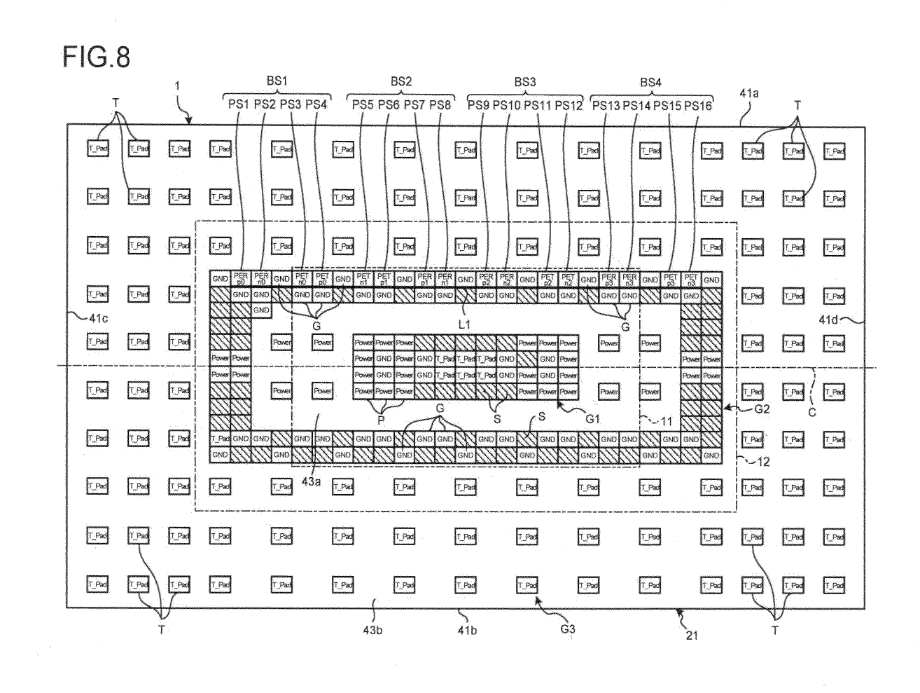

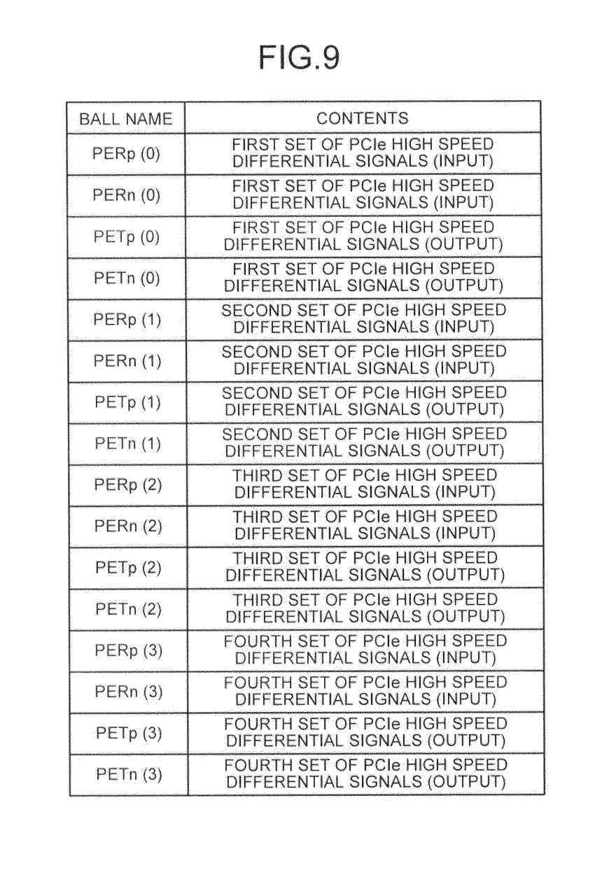

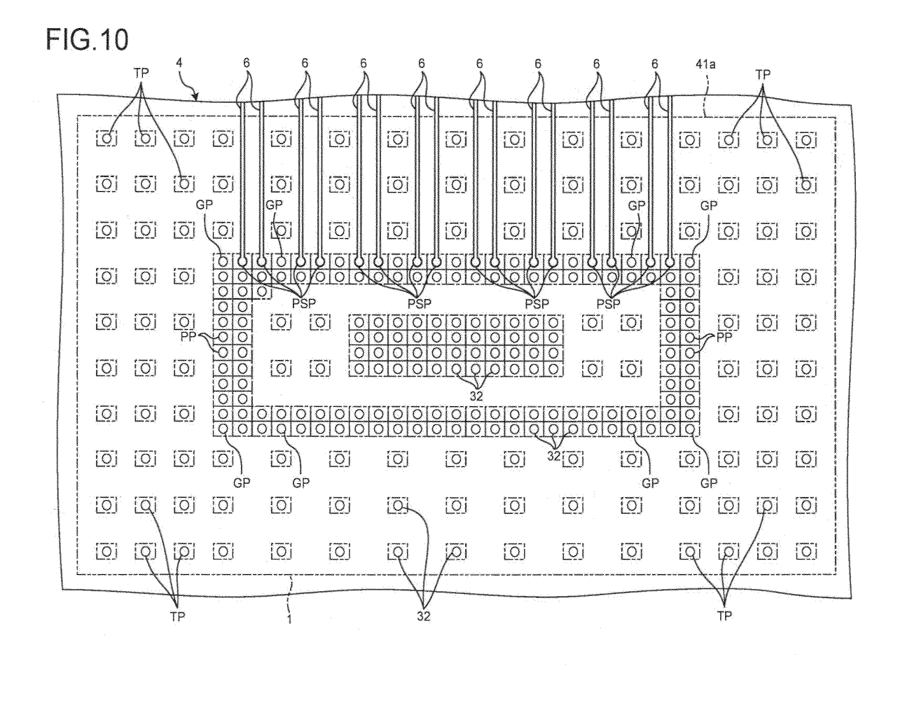

FIG. 8 schematically illustrates an assignment of the solder balls 27. Notably, for the convenience of explanation, FIG. 8 illustrates a ball arrangement with a posture of being mounted on the circuit board 4 as a reference (that is, with a posture of the semiconductor package 1 seen from above as the reference). FIG. 9 illustrates contents of the assignment illustrated in FIG. 8. FIG. 10 illustrates pads 32 of the circuit board 4 to which the solder balls 27 are connected.

The plurality of solder balls 27 of the embodiment includes PCIe signal balls PS1 to PS16, other signal balls S, power source balls P, ground balls G, and thermal balls T (heat diffuser balls). The PCIe signal balls PS1 to PS16 are an example of “differential signal balls”. Notably, in the following description, the PCIe signal balls PS1 to PS16, the other signal balls S, the power source balls P, and the ground balls G except the thermal balls T among the solder balls 27 may collectively be called functional balls E.

Further, in FIG. 8, the signal balls S are illustrated by hatching, the power source balls P are illustrated by “Power”, the ground balls G are illustrated by “GND”, and the thermal balls T are illustrated by “T_pad”. Hereinbelow, the arrangement of these solder balls 27 will be described in detail.

As illustrated in FIG. 8, the plurality of solder balls 27 is arranged by being divided into a first group G1, a second group G2, and a third group G3. The first group G1 is positioned at a center portion of the substrate 21. The first group G1 includes the plurality of thermal balls T provided at the center portion of the substrate 21, and the plurality of power source balls P, the ground balls G, and the signal balls S arranged to surround the plurality of thermal balls T.

The thermal balls T (heat diffuser balls) are electrically connected to a ground layer 29 or a power source layer 28 (that is, a copper layer) of the substrate 21. Due to this, heat from the controller chip 11 and the like easily transfers to the thermal balls T via the ground layer 29 or the power source layer 28.

The thermal balls T diffuses part of heat of the semiconductor package 1 to the circuit board 4. For example, in the embodiment, the controller chip 11 is positioned at the center portion of the substrate 21, and overlaps the thermal balls T of the first group G1. The controller chip 11 has larger heat generation upon its operation compared to other components (for example, the semiconductor memory chips 12 or the DRAM chip 13). The thermal balls T of the first group G1 diffuses part of the heat, which is transferred from the controller chip 11 to the substrate 21, to the circuit board 4.

The power source balls P are electrically connected to the power source layer 28 of the substrate 21, and supplies various types of electric power to the semiconductor package 1. The ground balls G are electrically connected to the ground layer 29 of the substrate 21, and serve as ground potential.

As illustrated in FIG. 8, the second group G2 is aligned in a frame shape surrounding the first group G1. A gap exists between the second group G2 and the first group G1. The second group G2 includes the PCIe signal balls PS1 to PS16, the signal balls S, the power source balls P, and the ground balls G.

Here, the PCIe signal balls PS1 to PS16 will be described in detail. As illustrated in FIGS. 8 and 9, the first PCIe signal ball PS1 corresponds to a first set of PCIe high speed differential signals (input, positive). The second PCIe signal ball PS2 corresponds to a first set of PCIe high speed differential signals (input, negative). The first and second PCIe signal balls PS1, PS2 become a differential pair in which a first differential signal flows.

The third PCIe signal ball PS3 corresponds to a first set of PCIe high speed differential signals (output, negative). The fourth PCIe signal ball PS4 corresponds to a first set of PCIe high speed differential signals (output, positive). The third and fourth PCIe signal balls PS3, PS4 become a differential pair in which a second differential signal flows.

Further, these four PCIe signal balls PS1, PS2, PS3, PS4 configure a first solder ball set BS1 (that is, a first lane) corresponding to a first signal set configured of a pair of a fast speed differential input signal and a fast speed differential output signal.

Similarly, the fifth PCIe signal ball PS5 corresponds to a second set of PCIe high speed differential signals (output, negative). The sixth PCIe signal ball PS6 corresponds to a second set of PCIe high speed differential signals (output, positive). The fifth and sixth PCIe signal balls PS5, PS6 become a differential pair in which a third differential signal flows.

The seventh PCIe signal ball PS7 corresponds to a second set of PCIe high speed differential signals (input, positive). The eighth PCIe signal ball PS8 corresponds to a second set of PCIe high speed differential signals (input, negative). The seventh and eighth PCIe signal balls PS7, PS8 become a differential pair in which a fourth differential signal flows.

Further, these four PCIe signal balls PS5, PS6, PS7, PS8 configure a second solder ball set BS2 (that is, a second lane) corresponding to a second signal set configured of a pair of a fast speed differential input signal and a fast speed differential output signal.

The ninth PCIe signal ball PS9 corresponds to a third set of PCIe high speed differential signals (input, positive). The tenth PCIe signal ball PS10 corresponds to a third set of PCIe high speed differential signals (input, negative). The ninth and tenth PCIe signal balls PS9, PS10 become a differential pair in which a fifth differential signal flows.

The eleventh PCIe signal ball PS11 corresponds to a third set of PCIe high speed differential signals (output, positive). The twelfth PCIe signal ball PS12 corresponds to a third set of PCIe high speed differential signals (output, negative). The eleventh and twelfth PCIe signal balls PS11, PS12 become a differential pair in which a sixth differential signal flows.

Further, these four PCIe signal balls PS9, PS10, PS11, PS12 configure a third solder ball set BS3 (that is, a third lane) corresponding to a third signal set configured of a pair of a fast speed differential input signal and a fast speed differential output signal.

The thirteenth PCIe signal ball PS13 corresponds to a fourth set of PCIe high speed differential signals (input, positive). The fourteenth PCIe signal ball PS14 corresponds to a fourth set of PCIe high speed differential signals (input, negative). The thirteenth and fourteenth PCIe signal balls PS13, PS14 become a differential pair in which a seventh differential signal flows.

The fifteenth PCIe signal ball PS15 corresponds to a fourth set of PCIe high speed differential signals (output, positive). The sixteenth PCIe signal ball PS16 corresponds to a fourth set of PCIe high speed differential signals (output, negative). The fifteenth and sixteenth PCIe signal balls PS15, PS16 become a differential pair in which an eighth differential signal flows.

Further, these four PCIe signal balls PS13, PS14, PS15, PS16 configure a fourth solder ball set BS4 (that is, a fourth lane) corresponding to a fourth signal set configured of a pair of a fast speed differential input signal and a fast speed differential output signal. In other words, the semiconductor package 1 of the embodiment includes four sets of solder ball sets configuring the PCIe lanes.

Here, the substrate 21 of the semiconductor package 1 includes four edges. The four edges include a first edge 41a, a second edge 41b, a third edge 41c, and a fourth edge 41d. In a state where the semiconductor package 1 is attached to the substrate 21, the first edge 41a is closest to the host controller 5 among the substrates 21. The first edge 41a is an end portion (that is an edge portion) that opposes the host controller 5. The first edge 41a extends substantially parallel to the host controller 5. The second edge 41b is positioned on an opposite side from the first edge 41a. The third edge 41c and the fourth edge 41d extend between the first edge 41a and the second edge 41b.

In the embodiment, the first to fourth solder ball sets BS1, BS2, BS3, BS4 are collectively arranged in the vicinity of the first edge 41a of the substrate 21. The first to fourth solder ball sets BS1, BS2, BS3, BS4 are positioned between the first edge 41a of the substrate 21 and the center portion of the substrate 21. The first to fourth solder ball sets BS1, BS2, BS3, BS4 are aligned substantially parallel to the first edge 41a of the substrate 21.

Accordingly, the first to fourth solder ball sets BS1, BS2, BS3, BS4 are positioned closer to the host controller 5 than the center portion of the substrate 21. That is, the first to fourth solder ball sets BS1, BS2, BS3, BS4 are positioned in a region between a center line C that passes a center of the substrate 21 while being substantially parallel to the first edge 41a, and the first edge 41a.

More specifically, in the embodiment, all of the PCIe signal balls PS1 to PS16 are aligned in a line along a first line L1. The first line L1 is positioned between the first edge 41a of the substrate 21 and the center portion of the substrate 21, and extends substantially parallel to the first edge 41a of the substrate 21.

As illustrated in FIG. 10, a plurality of pads 32 of the circuit board 4 is provided corresponding to the arrangement of the plurality of solder balls 27. The plurality of pads 32 of the circuit board 4 has the PCIe signal balls PS1 to PS16 connected thereto, and includes sixteen PCIe pads PSP through which PCIe signals flow with the host controller 5.

The circuit board 4 includes sixteen signal lines 6 (wiring pattern) that electrically connects the PCIe pads PSP and the host controller 5. The signal lines 6 are for example provided on a surface layer of the circuit board 4. The signal lines 6 extend linearly from the PCIe pads PSP toward the host controller 5. The signal lines 6 extend in a direction that substantially intersects orthogonally with the first edge 41a of the substrate 21 of the semiconductor package 1. The sixteen signal lines 6 have for example a same wiring length. That is, an isometric property of the signal lines 6 is ensured between the host controller 5 and the sixteen PCIe signal balls PS1 to PS16.

Next, an arrangement of the ground balls G will be described. Notably, the “PCIe signal balls” are simply read as “solder balls” herein for the sake of convenience of explanation.

Each of the solder ball sets BS1, BS2, BS3, BS4 respectively has two first solder balls corresponding to the differential input signals, and two second solder balls corresponding to the differential output signals. That is, the PCIe signal balls PS1, PS2, PS7, PS8, PS9, PS10, PS13, PS14 correspond to the first solder balls. On the other hand, the PCIe signal balls PS3, PS4, PS5, PS6, PS11, PS12, PS15, PS16 correspond to the second solder balls.

The ground balls G are arranged around the PCIe signal balls PS1 to PS16, and electrically shield between some of the PCIe signal balls PS1 to PS16. In the embodiment, the ground balls G are provided between the first solder balls and the second solder balls, between the solder ball sets BS1, BS2, BS3, BS4, and in each of the solder ball sets BS1, BS2, BS3, BS4.

That is, the ground balls G are provided between the differential pair and the differential pair. Owing to this, the pluralities of differential input signals and differential output signals are respectively shielded electrically so as to be independent of one another, whereby cross-talking of signals and influences of externally-introduced noises are suppressed.

Further, some of the ground balls G oppose the PCIe signal balls PS1 to PS16 from the opposite side of the signal lines 6. Therefore, the aforementioned eight differential signals are electrically shielded so as to be independent of other signals, and cross-talking of signals and influences of externally-introduced noises are suppressed.

As illustrated in FIG. 8, the third group G3 of the solder balls 27 includes a plurality of thermal balls T. The third group G3 is positioned on even outer side of the second group G2. The third group G3 is positioned between the second group G2 and an outer circumferential edge of the substrate 21 (four edges 41a, 41b, 41c, 41d). That is, the plurality of thermal balls T is positioned closer to the circumferential edge of the substrate 21 than the first to fourth solder ball sets BS1 to BS4.

The thermal balls T are arranged in a region between the first edge 41a of the substrate 21 and the first to fourth solder ball sets BS1 to BS4, in a direction that is substantially intersecting orthogonally with the first edge 41a of the substrate 21, while avoiding regions that align with the first to fourth solder ball sets BS1 to BS4. That is, the thermal balls T are arranged while avoiding the regions where the signal lines 6 passes. Therefore, the signal lines 6 can extend linearly on the surface layer of the circuit board 4 without being hindered by the thermal balls T.

From a different viewpoint, the thermal balls T are arranged in regions that are aligned in a direction that substantially intersects orthogonally with the first edge 41a of the substrate 21 relative to the ground balls G positioned between the PCIe signal balls PS1 to PS16. The thermal balls T are arranged between the plurality of signal lines 6 and on both sides of the signal lines 6. The thermal balls T are for example electrically connected to the ground layer 29 of the substrate 21, and contribute to suppressing the cross-talking of signals flowing in the signal line 6 and the influences of externally-introduced noises by being electric shields.

As illustrated in FIGS. 7 and 8, the substrate 21 includes a first region 43a and a second region 43b. The first region 43a is a region that overlaps the controller chip 11 in a plan view (that is, a projected region of the controller chip 11). On the other hand, the second region 43b is a region that is positioned on the outside of the first region 43a.

Here, an arrangement density of the thermal balls T in the second region 43b is higher than an arrangement density of the thermal balls T in the first region 43a. Notably, the “arrangement density” is defined by dividing the number of the thermal balls T arranged in each region by an area of each region.

Further, the second surface 21b of the substrate 21 is divided into a center region 43c, a first outer region 43d, and a second outer region 43e based on the arrangement of the solder balls 27. The center region 43c is a region that overlaps the controller chip 11 in the plan view as illustrated in FIG. 7, and is a region in which a plurality of thermal balls T is arranged, and the functional balls are arranged to surround the thermal balls T. The first outer region 43d is a region that overlaps the semiconductor memory chips 12 in the plan view, and is a ring-shaped region that surrounds a periphery of the center region 43c with a larger interval than a pitch of the solder balls 27 of the center region 43c. The functional balls E are arranged in the first outer region 43d at a same pitch as the pitch of the solder balls 27 in the center region 43c. The second outer region 43e is a region provided on the outside of the first outer region 43d. The thermal balls T are arranged in the second outer region 43e at a pitch that is larger than the pitch of the solder balls 27 in the center region 43c and the first outer region 43d, for example, twice as large as the pitch.

As illustrated in FIG. 10, the pads 32 of the circuit board 4 include thermal pads TP to which the thermal balls T are connected. The thermal pads TP are for example connected to the ground layer or the power source layer (that is, the copper layer) of the circuit board 4. Notably, the thermal balls T and the thermal pads TP are not limited to those connected to the substrate 21, or the ground layer or the power source layer of the circuit board 4. A constant heat diffusing effect can be obtained even by thermal balls T and thermal pads TP not connected to the copper layer.

Next, the arrangement of the power source balls P and the ground balls G will be described. As illustrated in FIG. 8, the plurality of power source balls P and the plurality of ground balls G are arranged to be substantially point symmetric relative to a center of the substrate 21. Notably, in addition to a case of a complete point symmetry, “substantially point symmetric” includes cases where a small number (for example, one) of ground balls G is not arranged in point symmetry, for example.

From a different viewpoint, one or the other of the plurality of power source balls P and the plurality of ground balls G may be arranged in point symmetry relative to the center of the substrate 21. In the embodiment, the plurality of power source balls P is arranged in point symmetry relative to the center of the substrate 21.

As illustrated in FIG. 10, the pads 32 of the circuit board 4 include power pads PP to which the power source balls P are connected, and ground pads GP to which the ground balls G are connected.

With the plurality of power source balls P and the plurality of ground balls G being arranged in substantial point symmetry, a corresponding relationship of the power source balls P and the power pads PP, as well as the ground balls G and the ground pads GP is maintained even if the semiconductor package 1 is erroneously attached to the circuit board 4 by rotating it by 180 degrees relative to a correct orientation.

According to such a configuration, the semiconductor package 1 with improved high speed operability can be provided. That is, for example, in a case where there is only one set of solder ball set corresponding to the high speed signal, there is a limit to fast speed operation.

Thus, the semiconductor package 1 of the embodiment includes the substrate 21, the seal portion 30, the controller chip 11, semiconductor chips (for example, the semiconductor memory chips 12), and the plurality of differential signal balls (for example, the PCIe signal balls PS1 to PS16). At least part of the plurality of differential signal balls is arranged substantially parallel to the first edge 41a of the substrate 21.

According to such a configuration, data amount that can be sent and received can be doubled by increasing the number of the solder ball sets corresponding to the high speed signal, whereby the high speed operability can be improved.

Moreover, when the plurality of differential signal balls is arranged substantially parallel to the first edge 41a of the substrate 21, isometric property of the signal lines 6 between the plurality of differential signal balls and the host controller 5 is more easily ensured by arranging the semiconductor package 1 so that the first edge 41a of the substrate 21 is directed toward the host controller 5. Therefore, signal quality sent and received by the semiconductor package 1 can be increased.

From a different viewpoint, the plurality of differential signal balls may arrange the differential pairs in the direction that substantially intersects orthogonally with the first edge 41a of the substrate 21, and may arrange the plurality of differential signal balls in two rows that are substantially parallel to the first edge 41a of the substrate 21. However, in this case, if the solder balls 27 are arranged at 0.5 mm pitch as in the embodiment, the arrangement of the differential signal balls and the signal lines 6 becomes dense, and a need to provide acute bending portion in some of the signal lines 6 arises. This may impose influence on the signal quality and reliability in some cases.

On the other hand, in the embodiment, the plurality of differential signal balls is arranged in a line that is substantially parallel to the first edge 41a of the substrate 21. According to such a configuration, the plurality of differential signal balls and the signal lines 6 are more unlikely to become dense, and the need to provide the acute bending portion in the signal lines 6 can be avoided. Accordingly, the signal quality and reliability can further be increased.

In the embodiment, the plurality of ground balls G is provided around the plurality of differential signal balls and electromechanically shields between some of the differential signal balls. Accordingly, the cross-talking of signals and the influences of externally-introduced noises in the plurality of differential signal balls are suppressed, and the signal quality can be increased.

In the embodiment, the plurality of solder balls 27 includes the plurality of thermal balls T that is electrically connected to the ground layer 29 or the power source layer 28 of the substrate 21. According to such a configuration, heat of the semiconductor package 1 can be diffused efficiently to the circuit board 4. Accordingly, temperature rise in the semiconductor package 1 can be suppressed, and the high speed operation of the semiconductor package 1 can be enhanced.

In the embodiment, the plurality of thermal balls T is positioned closer to the outer circumferential edge of the substrate 21 than the plurality of solder ball sets BS1 to BS4. According to such a configuration, a peripheral portion of the substrate 21 where wiring layout is sparse can be made full use to arrange the thermal balls T. Accordingly, degree of freedom of layout design of the semiconductor package 1 can be improved.

In the embodiment, the plurality of thermal balls T in the region between the first edge 41a of the substrate 21 and the solder ball sets BS1 to BS4 is arranged while avoiding the regions adjacent to each of the solder ball sets BS1 to BS4 in the direction that substantially intersects orthogonally with the first edge 41a of the substrate 21. Owing to this, the signal lines 6 can be linearly extended from the PCIe pads PSP of the circuit board 4. That is, the signal lines 6 no longer need to be detoured in order to avoid the thermal balls T. Therefore, the signal quality can further be improved.

Notably, the thermal balls T are not provided fully on an entire surface of the substrate 21 but preferably are at the least number that is necessary from the viewpoint of cost reduction of the semiconductor package 1. Accordingly, in a case where an upper limit is set to the number of the thermal balls T, it is also preferable to arrange a relatively large number of thermal balls T in the second region 43b of the substrate 21 from the viewpoint of heat diffusing property.

Here, arranging the plurality of thermal balls T intensively in the first region 43a may be considered. At first glance, better heat diffusing property may seem to be obtained with relatively larger number of thermal balls T being arranged in the first region 43a that is positioned just below the controller chip 11, which is the heat generating component.

However, according to test results obtained by the inventors, it has been found that the temperature rise in the semiconductor package 1 as suppressed to a lower level when a relatively larger number of thermal balls T are arranged in the second region 43b. This is assumed to be due to the increased heat diffusing property of the whole semiconductor package 1 when the thermal balls T are arranged dividedly in the second region 43b in addition to the first region 43a. Thus, in the embodiment, the relatively large number of thermal balls T is arranged in the second region 43b, and the heat diffusing property of the semiconductor package 1 is further increased.

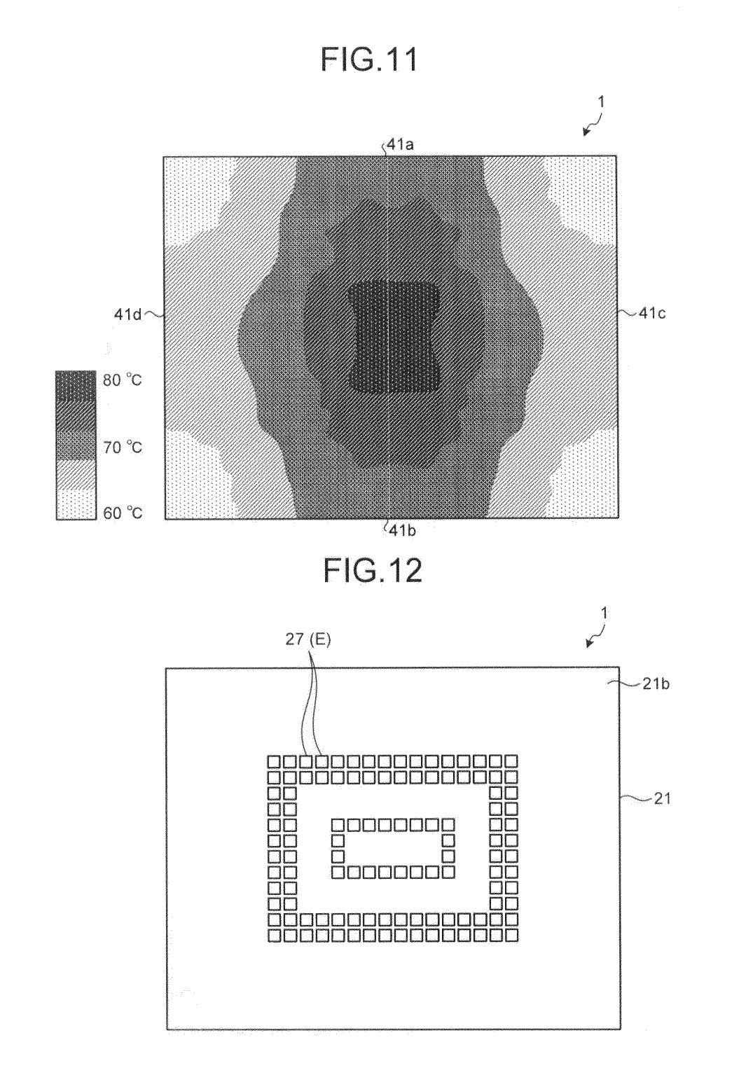

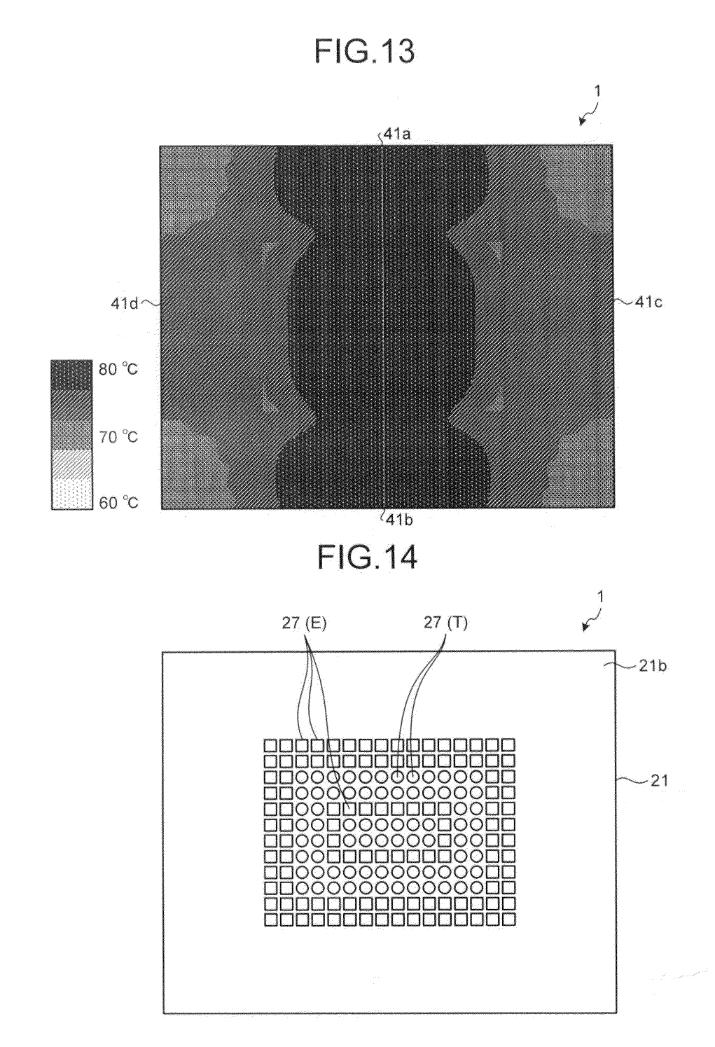

The arrangement and heat diffusing property of the aforementioned solder balls 27 (thermal balls T) will be described in detail with reference to the drawings. FIG. 11 is a plan diagram illustrating a temperature distribution in the semiconductor package 1 in the case of having arranged the solder balls 27 as illustrated in FIGS. 7 and 8. FIG. 12 is a bottom diagram of the semiconductor package illustrating another example of the arrangement of the solder balls 27 as a comparative example. FIG. 13 is a plan diagram illustrating a temperature distribution in the semiconductor package 1 in the case of arranging the solder balls 27 as illustrated in FIG. 12. Notably, the temperature distribution to be illustrated in FIG. 11, FIG. 13, and the following description indicates a temperature distribution in a case where eight pieces of semiconductor memory chips stacked in the semiconductor package are driven.

In the comparative example illustrated in FIG. 12, the solder balls 27 have the functional balls E arranged in the same arrangement as those illustrated in FIGS. 7 and 8, and the thermal balls T are omitted. Accordingly, the number of the solder balls 27 as a whole is decreased than in the example illustrated in FIGS. 7 and 8. Further, in comparing the temperature distribution in the semiconductor package in FIGS. 11 and 13, a range of which temperature is equal to or above 80° C. is wider in the case of having omitted the thermal balls T (the case of FIG. 13) than in the case of having provided the thermal balls T (the case of FIG. 11). Therefore, it can be confirmed that the temperature rise in the semiconductor package can be suppressed by the heat diffusing efficiency improved by providing the thermal balls T.

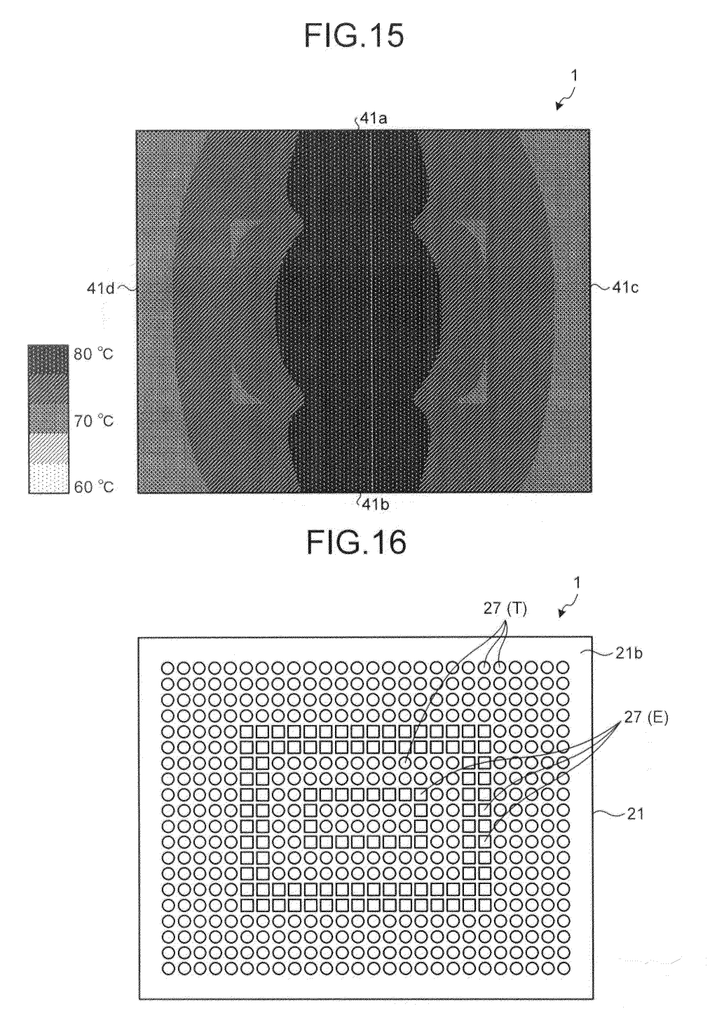

FIG. 14 is a bottom diagram of the semiconductor package illustrating another example of the arrangement of the solder balls 27 as another comparative example. FIG. 15 is a plan diagram illustrating a temperature distribution in the semiconductor package 1 in the case of arranging the solder balls 27 as illustrated in FIG. 14. In the comparative example illustrated in FIG. 14, the functional balls E are arranged in the same arrangement as those illustrated in FIGS. 7 and 8, and the thermal balls T are arranged inside the functional balls E arranged in double rows, that is, in a region that overlaps the semiconductor memory chips 12 in the plan view.

Further, in comparing the temperature distribution in the semiconductor package between FIGS. 11 and 15, in the case of arranging the thermal balls T in the region that overlaps the semiconductor memory chips 12 (the case of FIG. 15), the range of which temperature is equal to or above 80° C. is wider than in the case of having arranged the thermal balls T outside the region that overlaps the semiconductor memory chips 12 (the case of FIG. 11). Therefore, it can be confirmed that the temperature rise in the semiconductor package can be suppressed by the heat diffusing efficiency improved by providing the thermal balls T on the outer side of the region that overlaps the semiconductor memory chips 12.

Notably, there is scarcely any difference in the number of the arranged solder balls 27 between FIGS. 11 and 15. Further, in comparing FIGS. 13 and 15, a significant improvement in the heat diffusing efficiency cannot be seen despite the thermal balls T having been provided. Thus, it can be confirmed that the position where the thermal balls are arranged greatly influences the level of the heat diffusing efficiency.

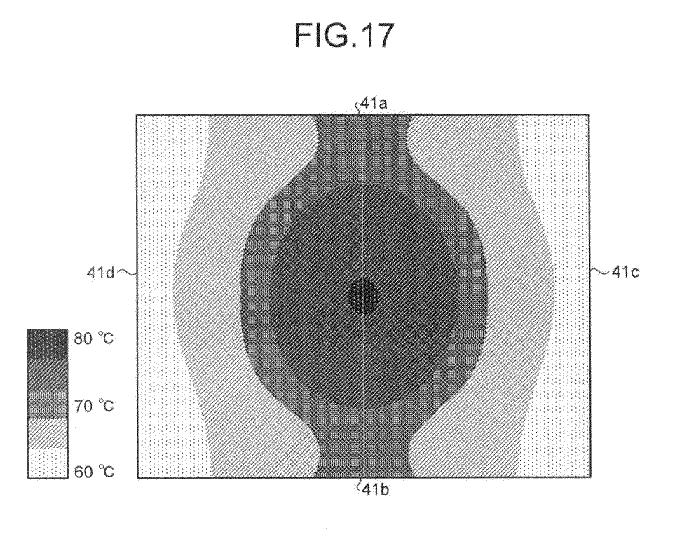

FIG. 16 is a bottom diagram of the semiconductor package illustrating another example of the arrangement of the solder balls 27 as yet another comparative example. FIG. 17 is a plan diagram illustrating a temperature distribution in the semiconductor package 1 in the case of arranging the solder balls 27 as illustrated in FIG. 16. In the comparative example illustrated in FIG. 16, the functional balls E are arranged in the same arrangement as those illustrated in FIGS. 7 and 8. Further, the thermal balls T are arranged both inside and outside the functional balls E arranged in double rows, that is, both regions that do not overlap with the region that overlaps the semiconductor memory chips 12 in the plan view. Further, in the regions that do not overlap with the semiconductor memory chips 12, the thermal balls T are arranged more densely than those in the example illustrated in FIGS. 7 and 8. Therefore, in the example illustrated in FIG. 16, the solder balls 27 are arranged about twice as much as in the example illustrated in FIGS. 7 and 8.

Moreover, in comparing the temperature distribution in the semiconductor package in FIGS. 11 and 17, in the example illustrated in FIG. 16, the improvement in the heat diffusing efficiency is limited despite the fact that about twice as many solder balls 27 as in the example illustrated in FIGS. 7 and 8 were provided. Accordingly, in the example illustrated in FIGS. 7 and 8, it can be confirmed that the improvement in the heat diffusing efficiency can be achieved and the temperature rise in the semiconductor package can be suppressed while suppressing the number of the solder balls 27. Notably, by suppressing the number of the solder balls 27, manufacturing cost of the semiconductor package can be suppressed.

In the embodiment, the plurality of solder balls 27 includes the plurality of power source balls P electrically connected to the power source layer 28 of the substrate 21, and the plurality of ground balls G electrically connected to the ground layer 29 of the substrate 21. The plurality of power source balls P and the plurality of ground balls G are arranged substantially point symmetric relative to the center of the substrate 21.

Here, in the case where the plurality of power source balls P and the plurality of ground balls G are not arranged in the substantial point symmetry, if the semiconductor package 1 is erroneously attached to the substrate 21 by rotating it by 180 degrees relative to the correct orientation, the power pads PP of the circuit board 4 and the ground balls G of the semiconductor package 1 may possibly be short circuited.

On the other hand, as in the embodiment, if the plurality of power source balls P and the plurality of ground balls G are arranged substantially point symmetric relative to the center of the substrate 21, the corresponding relationship of the plurality of power source balls P and the plurality of power pads PP, as well as the plurality of ground balls G and the plurality of ground pads GP is maintained even if the semiconductor package 1 is erroneously attached to the substrate 21 by rotating it by 180 degrees relative to the correct orientation. Therefore, the possibility of the occurrence of the short circuiting is eliminated, and damages to an entire system and the semiconductor package 1 can be prevented.

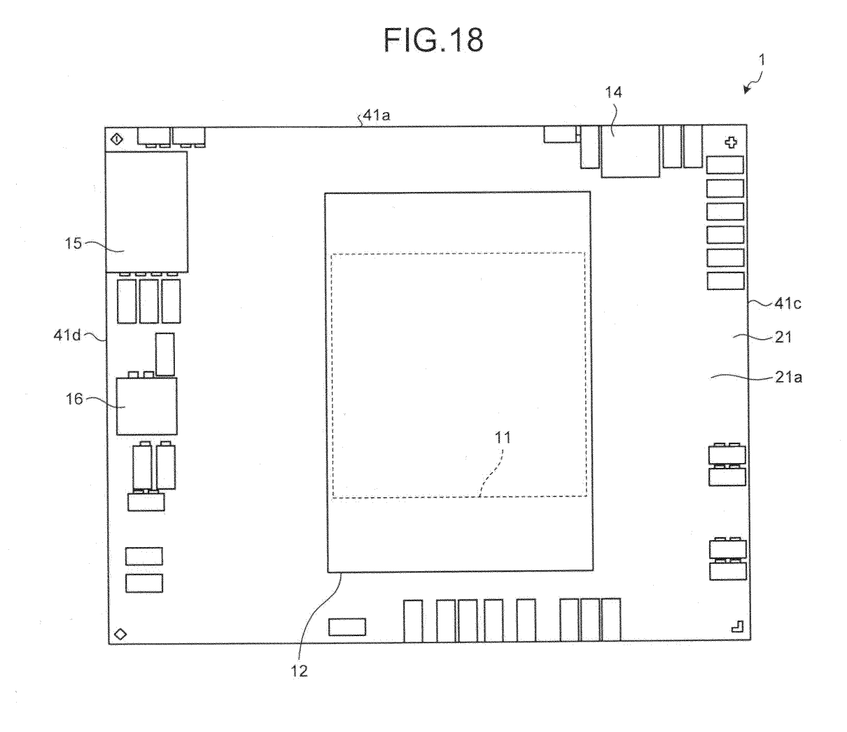

Next, the arrangement of the electronic components such as the temperature sensor 16 in the semiconductor package 1 will be described. FIG. 18 is a plan diagram for explaining a positional relationship of the electronic components arranged in the semiconductor package 1. As illustrated in FIG. 18, the temperature sensor 16 is provided at a position along one of the edges among the four edges of the substrate 21, at a center portion that is separated from corner portions of the substrate 21. For example, the temperature sensor 16 is provided at a position that is along the fourth edge 41d of the substrate 21, being a position that overlaps a region in which the controller chip 11 is offset in a direction parallel to the edges 41a to 41d of the substrate 21. In FIG. 18, the temperature sensor 16 is provided at the position that overlaps with the region in which the controller chip 11 is offset in the direction parallel to the first edges 41a.

As illustrated in FIG. 11, temperature becomes higher at the center portion of the edge than at the corner portions of the semiconductor package 1. Accordingly, it becomes possible to detect more quickly the temperature rise in the semiconductor package 1 by providing the temperature sensor 16 at the center portion of the edge than at the corner portions of the semiconductor package 1. Notably, as illustrated in FIG. 11, among the four edges 41a to 41d of the substrate 21, the portions of the edges 41a, 41b which are closer to the controller chip 11 have higher temperature than the edges 41c, 41d which are away from the chip. Accordingly, it becomes possible to detect more quickly the temperature rise in the semiconductor package 1 by providing the temperature sensor 16 at the portions of the edges 41a, 41b which are closer to the controller chip 11.

Temperature information detected by the temperature sensor 16 is sent to the controller chip 11. The controller chip 11 performs control to stop the operation of the semiconductor memory chips 12 or decrease the operation speed thereof in a case where the temperature information detected by the temperature sensor 16 becomes higher than a predetermined temperature, and restart the operation of the semiconductor memory chips 12 or recover the operation speed thereof after a predetermined time has elapsed.

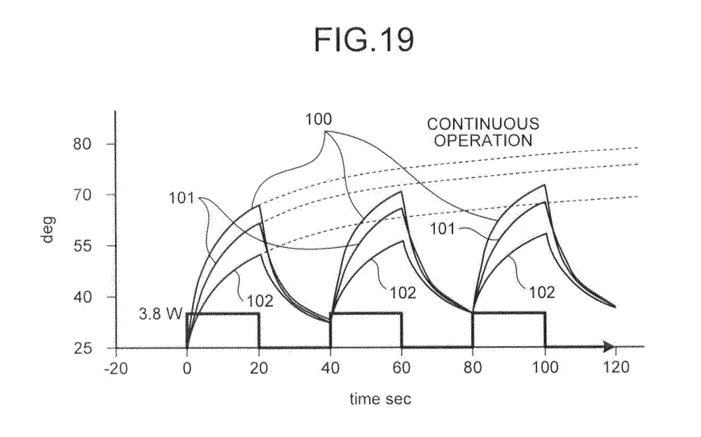

FIG. 19 is a diagram illustrating a temperature change in a case of operating the semiconductor memory chips 12 intermittently. In FIG. 19, the temperature change in the controller chip 11 in the semiconductor package 1 is illustrated by a line 100, the temperature change in the semiconductor memory chips 12 is illustrated by a line 101, and the temperature change in the center portion of the substrate 21 is illustrated by a line 102.

As illustrated in FIG. 19, by driving the semiconductor memory chips 12 intermittently, the temperature rise in the respective electronic components can be suppressed than in the case of driving them continuously. Accordingly, as aforementioned, the temperature rise in the semiconductor package 1 can be suppressed by stopping the operation of the semiconductor memory chips 12 or reducing the operation temperature thereof based on the detected temperature by the temperature sensor 16. By suppressing the temperature rise in the semiconductor package 1, the decrease in the operation speed caused by the temperature rise in the semiconductor package 1 can be suppressed. This can contributes to speeding up the operation speed of the semiconductor package 1.

Further, as illustrated in FIG. 18, an oscillator 14 and an EEPROM 15 are provided at positions along the edges 41a to 41d of the substrate 21, being positions close to the corner portions of the substrate 21. For example, the oscillator 14 is provided at the position along the first edge 41a of the substrate 21, being a position that does not overlap with the region in which the controller chip 11 is offset in the direction parallel to the edges 41a to 41d of the substrate 21. As illustrated in FIG. 11, since temperature is low in the vicinities of the corner portions of the substrate 21 compared to other regions, decrease of performances caused by temperature rise in the oscillator 14 and the EEPROM 15 can be suppressed.

### Second Embodiment

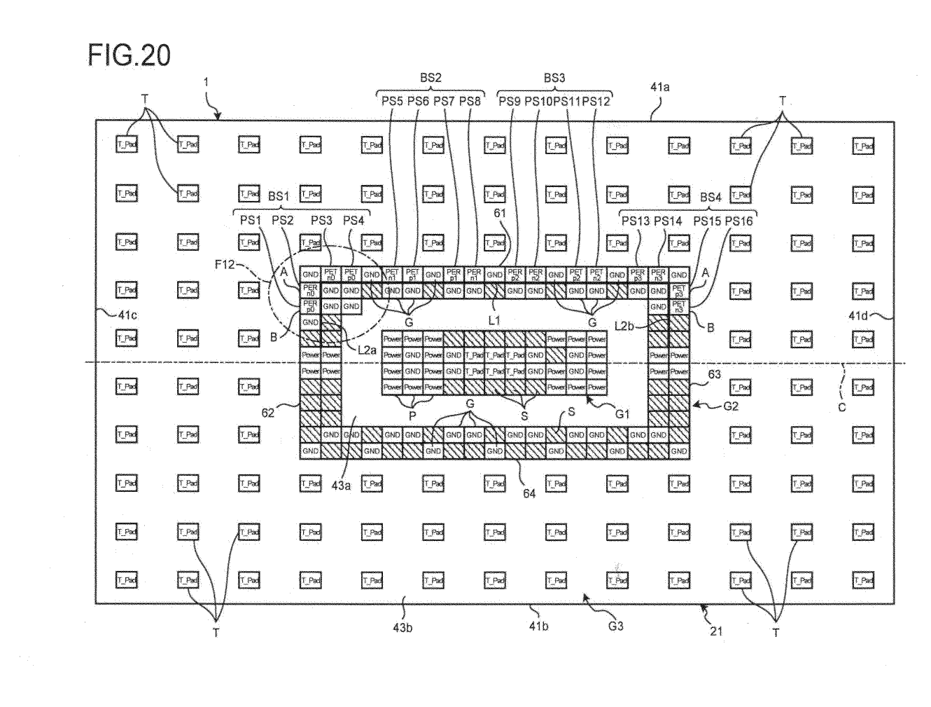

Next, a semiconductor package 1 of the second embodiment will be described with reference to FIGS. 20 to 25. Notably, configurations that are identical or have the same function as the configuration of the first embodiment will be given the same reference signs, and the description thereof will be omitted. Configurations other than those described below are the same as the first embodiment.

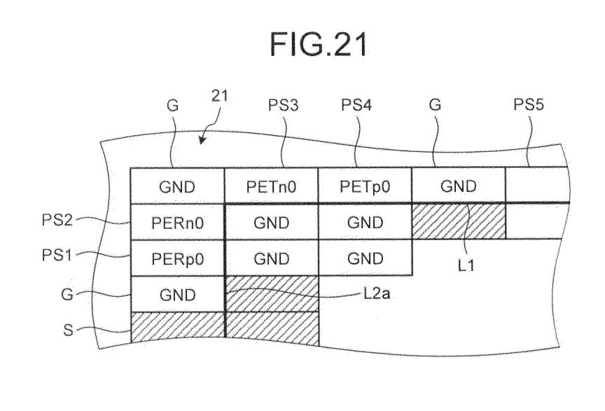

FIG. 20 illustrates an assignment of solder balls 27 of the embodiment. FIG. 21 illustrates a portion surrounded by F12 in FIG. 20 in enlarged manner. As illustrated in FIGS. 20 and 21, in the embodiment, a plurality of PCIe signal balls PS1 to PS16 is aligned along a first line L1 and a pair of second lines L2a, L2b. The first line L1 is positioned between a first edge 41a of a substrate 21 and a center portion of the substrate 21, and is substantially parallel to the first edge 41a of the substrate 21. The pair of second lines L2a, L2b extends from both end portions of the first line L1 in a direction separating away from the first edge 41a of the substrate 21.

That is, some of the PCIe signal balls PS1, PS2, PS15, PS16 positioned on the outermost side among the plurality of PCIe signal balls PS1 to PS16 are arranged in different orientations such that the PCIe signal balls PS1 to PS16 can be positioned along the second lines L2a, L2b which intersects (for example, intersecting substantially orthogonal) with the first line L1. Notably, the pair of second lines L2a, L2b is not limited to this name, and may be referred to for example as the second line L2a and a third line L2b.

In the embodiment, the PCIe signal balls PS5 to PS12 of second and third ball sets BS2, BS3 are arranged in a line along the first line L1. On the other hand, the PCIe signal balls PS1 to PS4, PS13 to PS16 of first and fourth ball sets BS1, BS4 are positioned on both sides of the second and third ball sets BS2, BS3, and at least a part of each of them is arranged along the pair of second lines L2a, L2b.

In this embodiment, also, all of the PCIe signal balls PS1 to PS16 of the first to fourth solder ball sets BS1, BS2, BS3, BS4 are positioned in a region between a center line C passing through a center of the substrate 21 while being substantially parallel to the first edge 41a, and the first edge 41a.

More specifically, a second group G2 arranged in a frame shape includes a first portion 61 (first edge), a second portion 62 (second edge), a third portion 63 (third edge), and a fourth portion 64 (fourth edge). The first portion 61 is aligned along the first line L1. The second portion 62 is arranged in a direction that substantially intersects orthogonally with the first portion 61 from a first end portion of the first portion 61.

The third portion 63 is arranged in the direction that substantially intersects orthogonally with the first portion 61 from a second end portion of the first portion 61, which is positioned on an opposite side from the first end portion. The second portion 62 and the third portion 63 are positioned separately on both sides of a first group G1. The fourth portion 64 is arranged substantially parallel to the first portion 61. The fourth portion 64 extends between the second portion 62 and the third portion 63. The first portion 61 and the fourth portion 64 are positioned separately from both sides of the first group G1.

In the embodiment, the PCIe signal balls PS5 to PS12 of second and third ball sets BS2, BS3 are arranged in a line at the first portion 61. Further, two PCIe signal balls PS3, PS4 of the first ball set BS1 are arranged at the first portion 61. The two PCIe signal balls PS13, PS14 of the fourth ball sets BS4 are arranged at the first portion 61.

On the other hand, two PCIe signal balls PS1, PS2 of the first ball set BS1 are arranged at an end portion of the second portion 62 connected to the first portion 61. Similarly, two PCIe signal balls PS15, PS16 of the fourth ball set BS4 are arranged at an end portion of the third portion 63 connected to the first portion 61.

Therefore, the plurality of PCIe signal balls PS1 to PS16 includes a plurality of first differential pairs arranged along the first line L1, and second differential pairs arranged along the pair of second lines L2a, L2b. That is, the PCIe signal balls (PS3, PS4), (PS5, PS6), (PS7, PS8), (PS9, PS10), (PS11, PS12), (PS13, PS14) respectively are examples of the first differential pair. On the other hand, the PCIe signal balls (PS1, PS2), (PS15, PS16) respectively are examples of the second differential pair.

Here, each of the second differential pairs includes a first ball A and a second ball B. The second ball B is positioned far away from the first edge 41a of the substrate 21 compared to the first ball A. In the embodiment, the PCIe signal balls PS2, PS15 are examples of the first ball A. The PCIe signal balls PS1, PS16 are examples of the second ball B.

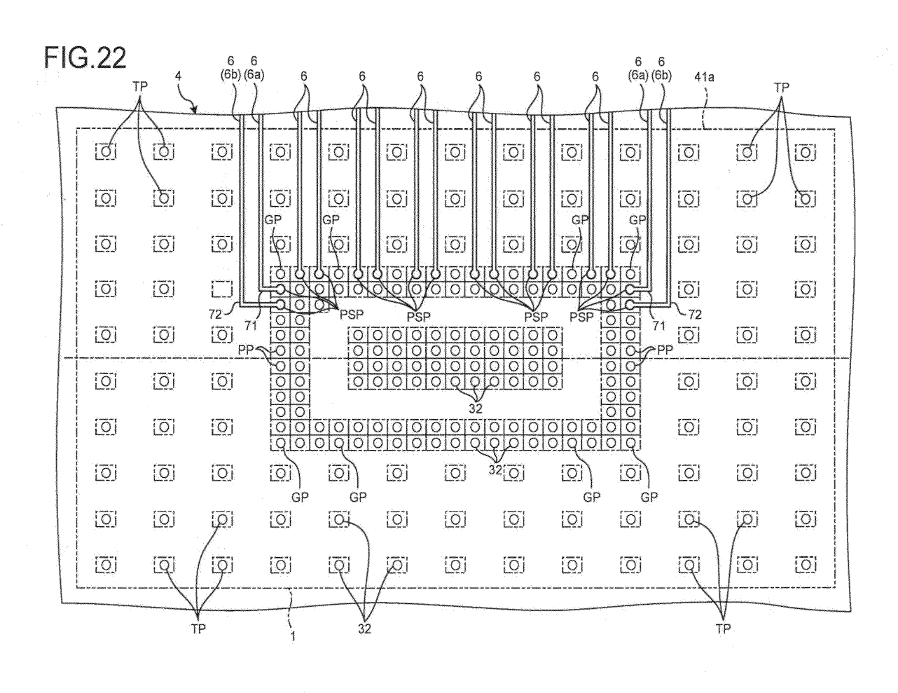

FIG. 22 illustrates an arrangement of pads 32 of a circuit board 4 of the embodiment. As illustrated in FIG. 22, signal lines 6 include four signal lines 6a, 6b extending between the PCIe signal balls (PS1, PS2), (PS15, PS16) configuring the second differential pairs and a host controller 5. These four signal lines 6a, 6b extend substantially parallel to the first edge 41a of the substrate 21 from PCIe pads PSP and include portions curving in a curved shape, and extend in a direction that substantially intersects orthogonally with the first edge 41a of the substrate toward the host controller 5.

Specifically, the signal lines 6 include first signal lines 6a extending between the first balls A and the host controller 5, and the second signal lines 6b extending between the second balls B and the host controller 5. The first signal line 6a includes a first curved portion 71. The second signal line 6b includes a second curved portion 72 that for example has a larger curvature of radius than the first curved portion 71, and is positioned outside the first curved portion 71. Each of the first and second curved portions 71, 72 is for example formed in an arc that is a quarter of a circle.

In the embodiment, all of the solder balls 27 including the plurality of ground balls G and the plurality of thermal balls T are arranged in the regions that avoid the first and second signal lines 6a, 6b having the curved portions 71, 72.

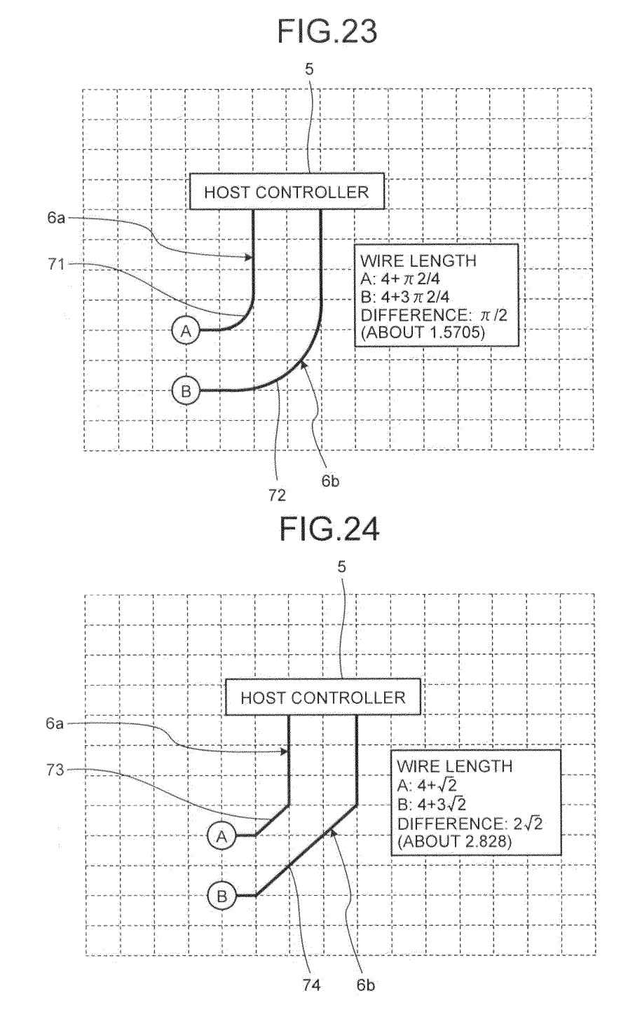

FIG. 23 schematically illustrates wire lengths of the signal lines 6 between the first and second balls A, B configuring the second differential pairs and the host controller 5. Notably, for the convenience of description, when portions have same influence to the wire lengths among the first balls A and the second balls B, the portions are illustrated by making the distances thereof short.

As illustrated in FIG. 23, in the embodiment, in a case where the distance between a first ball A and a second ball B is set to be 2, a difference in the wire lengths of the first signal lines 6a and the second signal lines 6b becomes n/2 (about 1.5705).

Next, with reference to FIG. 24, a first modification of the signal lines 6 will be described. Notably, configurations that are identical or have the same function as the configuration of the above embodiment will be given the same reference signs, and the description thereof will be omitted.

Signal lines 6 include four signal lines 6a, 6b extending between the PCIe signal balls (PS1, PS2), (PS15, PS16) configuring the second differential pairs and the host controller 5. These four signal lines 6a, 6b extend substantially parallel to the first edge 41a of the substrate 21 from the PCIe pads PSP and include portions extending obliquely relative to the first edge 41a of the substrate 21, and extend in the direction that substantially intersects orthogonally with the first edge 41a of the substrate toward the host controller 5.

Specifically, the first signal line 6a includes a first oblique portion 73 extending obliquely relative to the first edge 41a of the substrate 21. The second signal line 6b includes a second oblique portion 74 that for example is substantially parallel to the first oblique portion 73 and positioned outside the first oblique portion 73. The first and second oblique portions 73, 74 are for example inclined at an angle of 45° relative to the first edge 41a of the substrate 21.

In the embodiment, all of the solder balls 27 including the plurality of ground balls G and the plurality of thermal balls T are arranged in the regions that avoid the first and second signal lines 6a, 6b having the oblique portions 73, 74.

FIG. 24 schematically illustrates wire lengths of the signal lines 6 between the first and second balls A, B configuring the second differential pairs and the host controller 5. Notably, for the convenience of description, portions with same influence to the wire lengths among the first balls A and the second balls B are illustrated by making the distances thereof short.

As illustrated in FIG. 24, in the embodiment, in the case where the distance between the first ball A and the second ball B is set to be 2, the difference in the wire lengths of the first signal lines 6a and the second signal lines 6b becomes 2√2 (about 2.828).

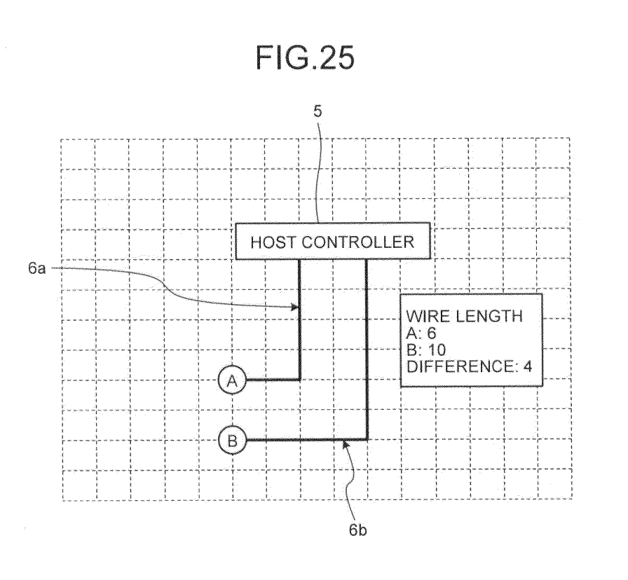

Next, with reference to FIG. 25, a second modification of the signal lines 6 will be described. Notably, configurations that are identical or have the same function as the configuration of the above embodiment will be given the same reference signs, and the description thereof will be omitted.

Signal lines 6 include four signal lines 6a, 6b extending between the PCIe signal balls (PS1, PS2), (PS15, PS16) configuring the second differential pairs and the host controller 5. These four signal lines 6a, 6b extend substantially parallel to the first edge 41a of the substrate 21 from the PCIe pads PSP, are bent substantially at the right angle, and extend in the direction that substantially intersects orthogonally with the first edge 41a of the substrate 21 toward the host controller 5. All of the solder balls 27 including the plurality of ground balls G and the plurality of thermal balls T are arranged in the regions that avoid the first and second signal lines 6a, 6b.

FIG. 25 schematically illustrates wire lengths of the signal lines 6 between the first and second balls A, B configuring the second differential pairs and the host controller 5. Notably, for the convenience of description, portions with same influence to the wire lengths among the first balls A and the second balls B are illustrated by making the distances thereof short.

As illustrated in FIG. 25, in the embodiment, in the case where the distance between a first ball A and a second ball B is set to be 2, the difference in the wire lengths of the first signal lines 6a and the second signal lines 6b becomes 4.

According to the configurations of the second embodiment and the modifications thereof as described above, similar to the first embodiment, a semiconductor package 1 in which the high speed operability can be improved, and further, connection reliability of the differential signal balls can be improved can be provided.

Generally, a peripheral end portion of the substrate 21 is for example a region in which the connection reliability of the solder balls 27 may possibly become low by thermal stress upon mounting of the semiconductor package 1. Therefore, if the differential signal balls are arranged near the peripheral end portion of the substrate 21, there is the possibility that the connection reliability of those differential signal balls becomes low.

Thus, in the embodiment, the plurality of differential signal balls (for example, the PCIe signal balls PS1 to PS16) is arranged along the first line L1 which is substantially parallel to the first edge 41a of the substrate 21, and the pair of second lines L2a, L2b extending in the direction separating away from the first edge 41a of the substrate 21 from both end portions of the first line L1.

According to such a configuration, for example, compared to the structure of the first embodiment, all of the differential signal balls can be arranged away from the peripheral end portion of the substrate 21. Therefore, the connection reliability of the differential signal balls can be increased.

In the embodiment, the plurality of differential signal balls includes the plurality of first differential pairs arranged along the first line L1, and the second differential pairs arranged along the pair of second lines L2a, L2b. According to such a configuration, the isometric property of the signal lines 6a, 6b of the second differential pairs is easily ensured. Accordingly, the signal quality of the signals which the differential signal balls arranged along the second lines L2a, L2b send and receive can be increased.

In the embodiment, the first and second signal lines 6a, 6b extend substantially parallel to the first edge 41a of the substrate 21 from the PCIe pads PSP, and extend toward the host controller 5 while including the curved portions 71, 72. According to such a configuration, for example, compared to the structure of the second modification of the embodiment, the difference in the wire lengths of the first and second signal lines 6a, 6b can be made small. Therefore, the signal quality of the signals that the differential pairs arranged along the second lines L2a, L2b send and receive can be increased.

Similarly, the first and second signal lines 6a, 6b of the first modification of the embodiment extend substantially parallel to the first edge 41a of the substrate 21 from the PCIe pads PSP, and extend toward the host controller 5 while including the oblique portions 73, 74. According to such a configuration, for example, compared to the structure of the second modification, the difference in the wire lengths of the first and second signal lines 6a, 6b can be made small. Therefore, the signal quality of the signals that the differential pairs arranged along the second lines L2a, L2b send and receive can be increased.

### Third Embodiment

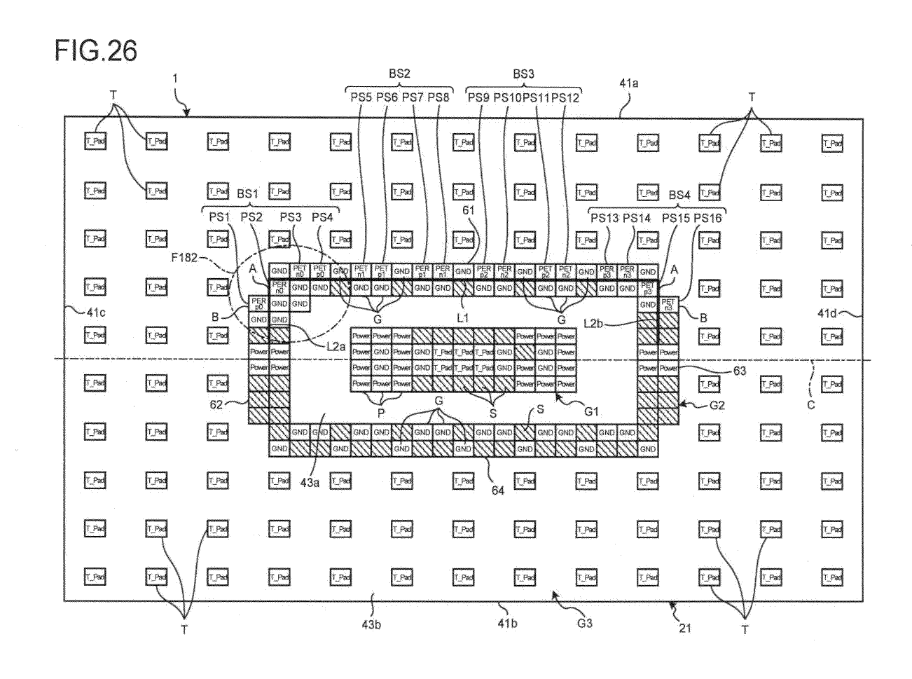

Next, a semiconductor package 1 of the third embodiment will be described with reference to FIGS. 26 to 28. Notably, configurations that are identical or have the same function as the configuration of the first and second embodiments will be given the same reference signs, and the description thereof will be omitted. Configurations other than those described below are the same as the second embodiment.

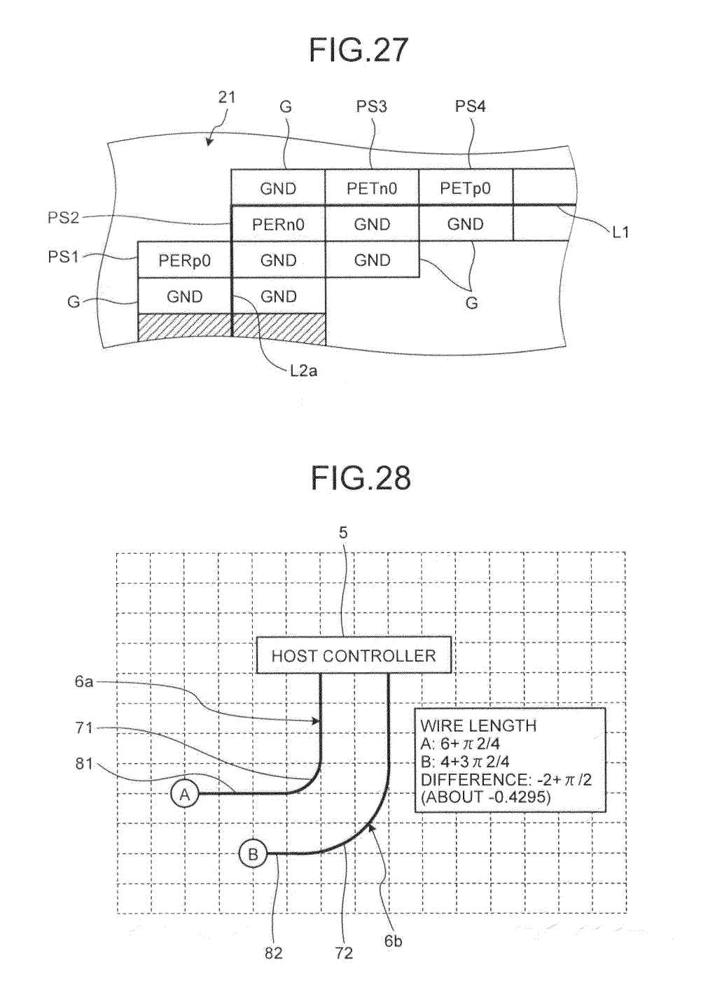

FIG. 26 illustrates an assignment of solder balls 27 of the embodiment. FIG. 27 illustrates a portion surrounded by F182 in FIG. 26 in enlarged manner. FIG. 28 illustrates an arrangement of pads 32 of the embodiment.

In the embodiment, PCIe signal balls (PS1, PS2), (PS15, PS16) configuring second differential pairs include first balls A, and second balls B positioned far away from a first edge 41a of a substrate 21 than the first balls A, similar to the second embodiment.

In the embodiment, for example, the first ball A is arranged such that the first ball A is offset to the inner side of the substrate 21 (center side) relative to the second ball B in a direction substantially parallel to the first edge 41a of the substrate 21. Notably, “arranged while being offset to the inner side of a substrate (center side) relative to the second ball” means that the first ball A is arranged while being offset toward a center portion of a first portion 61 of a second group G2 relative to the second ball B. In other words, it means that the first ball A is arranged while being offset toward a center portion of the first edge 41a of the substrate 21 relative to the second ball B.

In yet another way of saying, in a case where solder balls 27 are arranged in double rows of frame shape (shape of double frames) in the second group G2, the second balls B are positioned in the outer frame, and the first balls A are positioned in the inner frame.

As illustrated in FIG. 28, a first signal line 6a includes a first straight portion 81 between the first ball A and a first curved portion 71. The first straight portion 81 extends substantially parallel to the first edge 41a of the substrate 21. A second signal line 6b includes a second straight portion 82 between the second ball B and a second curved portion 72. The second straight portion 82 extends substantially parallel to the first edge 41a of the substrate 21. The first straight portion 81 is longer than the second straight portion 82.

As illustrated in FIG. 28, in a case where the distance between the first ball A and the second ball B is set to be 2, and the first ball A is arranged offset by distance 2 toward the inside of the substrate 21 relative to the second ball B, a difference in wire lengths of the first signal line 6a and the second signal line 6b becomes −2+π/2 (about −0.4295).

According to such a configuration, similar to the first embodiment, a semiconductor package 1 which can improve the high speed operability can be provided. Further, according to this configuration, similar to the second embodiment, since all of the differential signal balls can be arranged away from the peripheral end portion of the substrate 21, the connection reliability of the differential signal balls can be increased.

In the embodiment, the first ball A is arranged while being offset to the inner side of the substrate 21 (center side) relative to the second ball B. According to such a configuration, for example, compared to the structure of the second embodiment, the isometric property of the first and second signal lines 6a, 6b is more easily ensured. Therefore, the signal quality of the signals that the differential pairs arranged along the second lines L2a, L2b send and receive can be increased.

### Fourth Embodiment

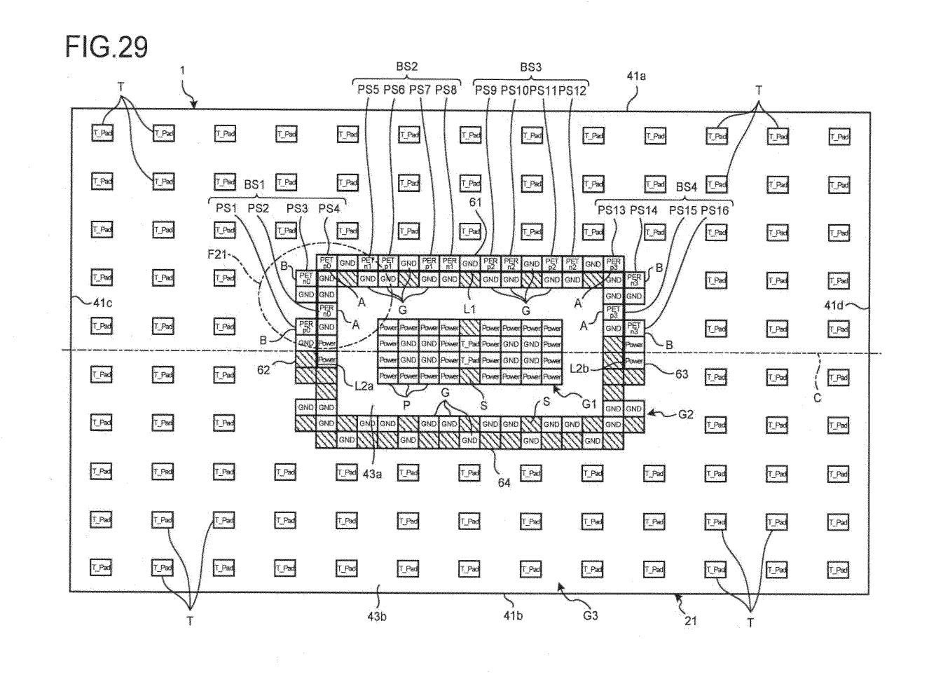

Next, a semiconductor package 1 of the fourth embodiment will be described with reference to FIGS. 29 to 31. Notably, configurations that are identical or have the same function as the configuration of the first to third embodiments will be given the same reference signs, and the description thereof will be omitted. Configurations other than those described below are the same as the third embodiment.

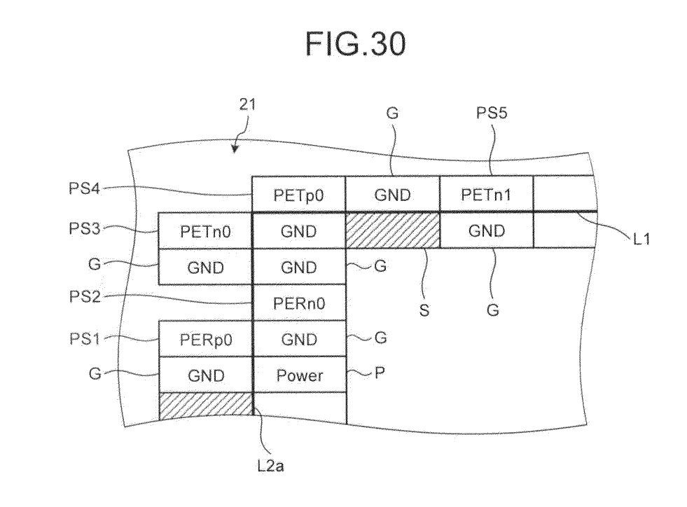

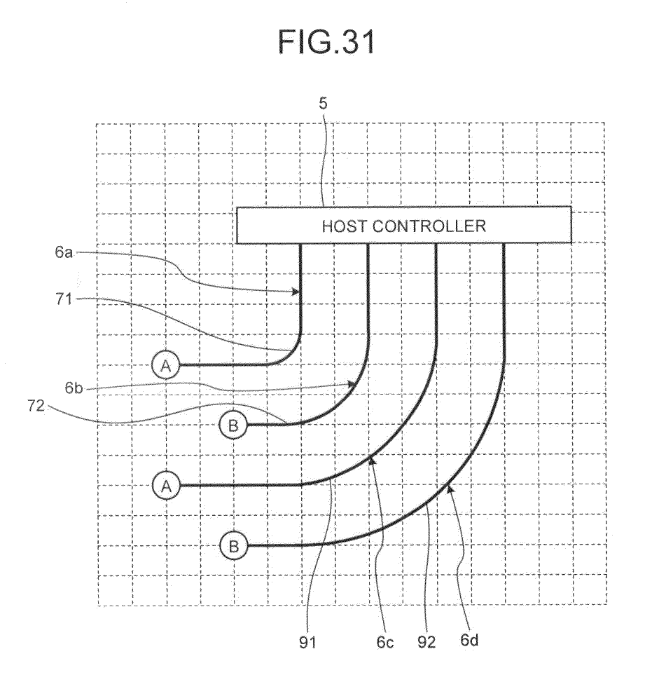

FIG. 29 illustrates an assignment of solder balls 27 of the embodiment. FIG. 30 illustrates a portion surrounded by F21 in FIG. 29 in enlarged manner. FIG. 31 schematically illustrates part of signal lines of the embodiment.

In the embodiment, a plurality of PCIe signal balls PS1 to PS16 includes a plurality of first differential pairs arranged along a first line L1, and pluralities of second differential pairs arranged along respective ones of a pair of second lines L2a, L2b. That is, in the embodiment, a plurality of second differential pairs is arranged along one second line L2a. Further, a plurality of second differential pairs is arranged along the other second line L2b.

Specifically, two differential pairs (PS1, PS2), (PS3, PS4) of a first solder ball set BS1 are arranged along the one second line L2a. Two differential pairs (PS13, PS14), (PS15, PS16) of a fourth solder ball set BS4 are arranged along the other second line L2b.

Here, signal lines 6 for the differential pairs arranged along the one second line L2a will be described. Notably, the differential pairs arranged along the other second line L2b have substantially the same configuration.

The signal lines 6 include a first signal line 6a and a second signal line 6b corresponding to one differential pair (PS3, PS4), and a third signal line 6c and a fourth signal line 6d corresponding to the other differential pair (PS1, PS2).

The first signal line 6a extends between the first ball A of the one differential pair (PS3, PS4) and a host controller 5. The second signal line 6b extends between the second ball B of the same differential pair (PS3, PS4) and the host controller 5.

The third signal line 6c extends between the first ball A of the other differential pair (PS1, PS2) and the host controller 5. The fourth signal line 6d extends between the second ball B of the same differential pair (PS1, PS2) and the host controller 5.

The first signal line 6a includes a first curved portion 71. The second signal line 6b includes a second curved portion 72 that for example has a larger curvature of radius than the first curved portion 71, and is positioned outside the first curved portion 71. The third signal line 6c includes a third curved portion 91 positioned outside the second curved portion 72. Notably, the third curved portion 91 may have a larger curvature of radius than the second curved portion 72, or may alternatively not. The fourth signal lines 6d includes a fourth curved portion 92 which for example has a larger curvature of radius than the third curved portion 91, and is positioned outside the third curved portion 91.

According to such a configuration, similar to the first embodiment, a semiconductor package 1 that can improve the high speed operability can be provided.

In the embodiment, the plurality of differential signal balls includes the plurality of first differential pairs arranged along the first line L1, and the plurality of second differential pairs arranged along the second lines L2a, L2b. According to such a configuration, for example, compared to the structure of the second embodiment, all of the differential signal balls can be arranged away from a peripheral end portion of the substrate 21. Therefore, the connection reliability of the differential signal balls can further be increased.

### Fifth Embodiment

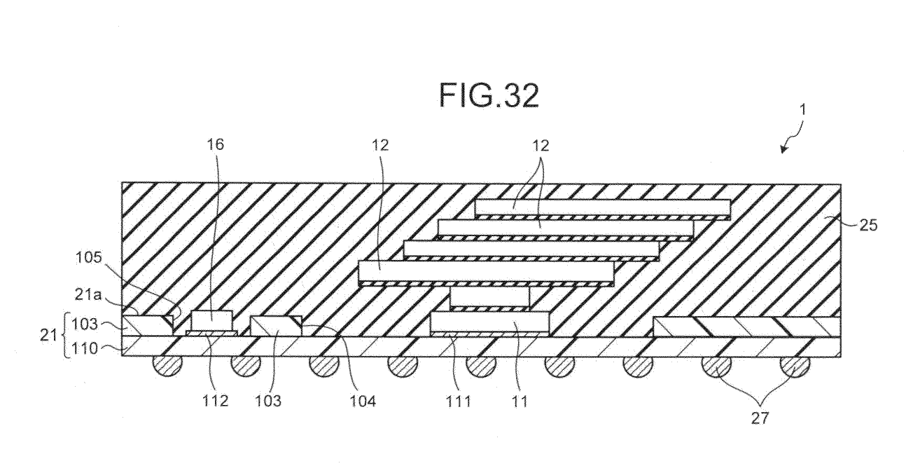

Next, a semiconductor package 1 of the fifth embodiment will be described with reference to FIG. 32. FIG. 32 is a cross sectional diagram of the semiconductor package 1 of the fifth embodiment. Notably, configurations that are identical or have the same function as the configuration of the first to fourth embodiments will be given the same reference signs, and the description thereof will be omitted. In the fifth embodiment, a connection unit (not illustrated) is provided at a lower surface of a controller chip 11. The connection unit electrically connects the controller chip 11 and a substrate 21 instead of the aforementioned bonding wires 22.

The substrate 21 is provided with an insulating substrate 110 inside of which a wiring layer of a power source layer 28 and a ground layer 29 (see also FIG. 4, etc.) is formed. A solder resist layer 103 covering the insulating substrate 110 is formed on a first surface 21a side of the substrate 21. The solder resist layer 103 has a first opening 104 and a second opening 105 formed therein, and the insulating substrate 110 and connecting pads 111, 112 are exposed through the openings 104, 105. The connecting pads 111, 112 are electrically connected with the wiring layer inside the insulating substrate 110.

The first opening 104 is formed at a portion where the controller chip 11 is fixed. The connecting pad 111 is formed at the portion of the insulating substrate 110 exposed through the first opening 104. The controller chip 11 and the substrate 21 are electrically connected via the connecting pads 111 and the connecting section by fixing the controller chip 11 by superimposing the connecting section on the connecting pads 111. The connecting pads 111 and the connecting section are, for example, bonded by solder.

The second opening 105 is formed at a portion where a temperature sensor 16 is fixed. The connecting pad 112 is formed at the portion of the insulating substrate 110 exposed through the second opening 105. The temperature sensor 16 and the substrate 21 are electrically connected by fixing the temperature sensor 16 on the connecting pad 112.

At least one edge of the first opening 104 is positioned outside an outer edge of a semiconductor memory chip 12 formed on the lowermost layer in the plan view. This makes a molding portion 25 easier to enter between the semiconductor memory chip 12 formed on the lowermost layer and the substrate 21, and an occurrence of void can be suppressed.

By employing the arrangement of the temperature sensor 16 and the intermittent operation exemplified in the first embodiment also to the semiconductor package 1 configured as above, temperature rise in the semiconductor package 1 can be suppressed.

### Sixth Embodiment

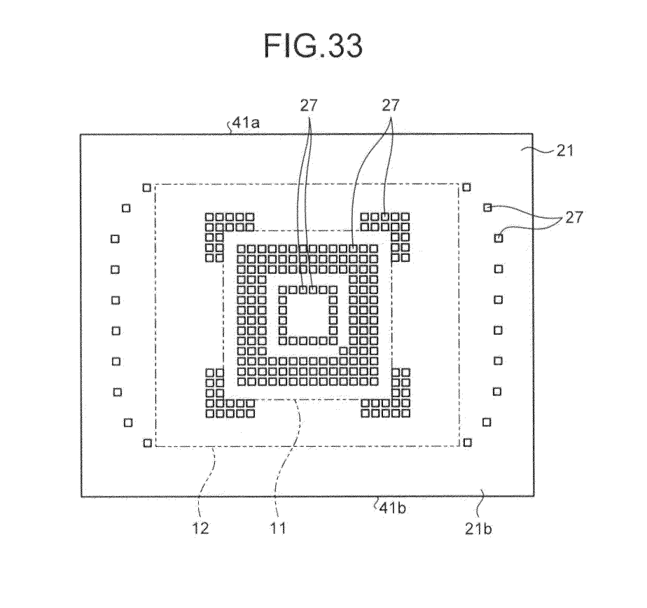

Next, an arrangement of solder balls 27 in a semiconductor package 1 of the sixth embodiment will be described with reference to FIG. 33. FIG. 33 is a lower surface diagram illustrating an example of a lower surface of the semiconductor package 1 of the sixth embodiment. Notably, configurations that are identical or have the same function as the configuration of the first to fifth embodiments will be given the same reference signs, and the description thereof will be omitted.

In the sixth embodiment, solder balls 27 are formed in two rows with an interval in a region that overlaps a controller chip 11 in a plan view. Further, solder balls 27 are formed also around corner portions of the controller chip 11 in a region that overlaps semiconductor memory chips 12 in the plan view. Further, solder balls 27 are formed by being arranged in arc shapes outside a pair of edges of the semiconductor memory chip 12 opposing each other among edges of the semiconductor memory chip 12 in the plan view, while connecting end portions of respective edges.

By employing the arrangement of the temperature sensor 16 and the intermittent operation exemplified in the first embodiment also to the semiconductor package 1 in which the solder balls 27 are arranged as aforementioned, temperature rise in the semiconductor package 1 can be suppressed.

Notably, the invention is not limited to the exact configurations of the above embodiments, but can be implemented by making modifications to the constituent features within the scope that does not deviate from the essence thereof upon carrying it out into practice. Further, various inventions can be formed by suitably combining the plurality of constituent features disclosed in the above embodiments. For example, some of the constituent features may be deleted from the entire constituent features exemplified in the embodiments. Moreover, constituent features in different embodiments may suitably be combined. For example, as the third and fourth signal lines 6c, 6d of the semiconductor package 1 of the third embodiment, shapes of the signal lines as in the first and second modifications of the second embodiment may be employed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor package comprising:
a package substrate including a first surface;
a controller chip provided on the first surface of the package substrate;
a semiconductor memory chip provided on the first surface;
a temperature sensor provided at a position along an edge of the first surface, which is at a center portion separated away from corner portions;
a seal portion provided on the first surface and configured to cover the controller chip, the semiconductor memory chip, and the temperature sensor; and
a plurality of solder balls provided on a second surface that is at an opposite side of the first surface.

2. The semiconductor package according to claim 1, wherein the semiconductor memory chip is stacked on the controller chip.

3. The semiconductor package according to claim 2, wherein the position where the temperature sensor is provided is a position that overlaps a region to which the controller chip is moved along one edge of the first surface.

4. The semiconductor package according to claim 2, wherein the temperature sensor is provided at the position along an edge among four edges of the first surface, the edge being closest to the controller chip in a plan view.

5. The semiconductor package according to claim 2, further comprising an EEPROM provided in the vicinity of the corner portion of the first surface,
wherein the seal portion covers the EEPROM.

6. The semiconductor package according to claim 2, further comprising an oscillator provided in the vicinity of the corner portion of the first surface,
wherein the seal portion covers the oscillator.

7. The semiconductor package according to claim 2, wherein the solder balls include a plurality of heat diffuser balls electrically connected to a ground layer or a power source layer of the package substrate, and functional balls other than the heat diffuser balls.

8. The semiconductor package according to claim 7, wherein
the first surface of the package substrate includes a center region, a first outer region, and a second outer region,
the center region is a region that overlaps the controller chip in the plan view, and is a region in which the plurality of heat diffuser balls is arranged, and the functional balls are arranged to surround the heat diffuser balls,
the first outer region is a region that overlaps the semiconductor memory chip in the plan view, and is a region that surrounds a periphery of the center region with an interval that is larger than a pitch of the solder balls in the center region,
the functional balls are arranged in the first outer region at a same pitch as the pitch of the solder balls in the center region,
the second outer region is a region provided outside the first outer region, and
thermal balls are arranged in the second outer region at a pitch that is larger than the pitch of the solder balls in the center region and the first outer region.

9. The semiconductor package according to claim 2, further comprising a DRAM chip provided on the first surface,
wherein the seal portion covers the DRAM chip.

10. The semiconductor package according to claim 2, wherein
the package substrate includes an insulating substrate inside of which a wiring layer is formed, and a solder resist layer covering the insulating substrate, and
a first opening for exposing the insulating substrate is formed in a region of the solder resist layer where the controller chip is to be provided.

11. The semiconductor package according to claim 10, wherein a connecting pad configured to electrically connect the controller chip and the wiring layer is formed at a portion within the insulating substrate exposed from the first opening.

12. The semiconductor package according to claim 2, wherein
the package substrate includes an insulating substrate inside of which a wiring layer is formed, and a solder resist layer covering the insulating substrate, and
a second opening for exposing the insulating substrate is formed in a region of the solder resist layer where the temperature sensor is to be provided.

13. The semiconductor package according to claim 12, wherein a connecting pad configured to electrically connect the temperature sensor and the wiring layer is formed at a portion within the insulating substrate exposed from the second opening.

14. The semiconductor package according to claim 2, wherein the seal portion includes a first molding portion configured to cover the controller chip, and a second molding portion configured to cover the semiconductor memory chip.

15. The semiconductor package according to claim 14, wherein the semiconductor memory chip is provided on the first molding portion.

16. The semiconductor package according to claim 2, wherein the controller chip performs control to stop an operation of the semiconductor memory chip or reduce an operation speed in a case where a temperature detected by the temperature sensor becomes higher than a predetermined temperature.

17. The semiconductor package according to claim 2, wherein the semiconductor memory chip is a nonvolatile memory.

18. The semiconductor package according to claim 17, wherein the nonvolatile memory is a NAND flash memory.

19. The semiconductor package according to claim 1, wherein the controller chip and the semiconductor memory chip are provided at positions where they do not overlap each other.

20. An electronic apparatus comprising:
a semiconductor package that includes: a package substrate including a first surface; a controller chip provided on the first surface of the package substrate; a semiconductor memory chip stacked on the controller chip; a temperature sensor provided at a position along an edge of the first surface, which is at a center portion separated away from corner portions; a seal portion provided on the first surface and configured to cover the controller chip, the semiconductor memory chip, and the temperature sensor; and a plurality of solder balls provided on a second surface that is at an opposite side of the first surface;
a circuit board on which the semiconductor package is mounted; and
a host controller provided on the circuit board, and configured to control the controller chip and the semiconductor memory chip.
